(19) United States
(12) Patent Application Publication
(10) Pub. No.: US 2017/0130320 A1
(43) Pub. Date: May 11, 2017

(54) MASK FOR PRODUCTION OF ORGANIC ELECTROLUMINESCENT ELEMENT, APPARATUS FOR PRODUCING ORGANIC ELECTROLUMINESCENT ELEMENT, AND METHOD FOR PRODUCING ORGANIC ELECTROLUMINESCENT ELEMENT

(71) Applicant: Sharp Kabushiki Kaisha, Sakai City, Osaka (JP)

(72) Inventors: Yuhki KOBAYASHI, Sakai City (JP); Katsuhiro KIKUCHI, Sakai City (JP); Shinichi KAWATO, Sakai City (JP); Takashi OCHI, Sakai City (JP); Kazuki MATSUNAGA, Sakai City (JP); Satoshi INOUE, Sakai City (JP); Eiichi MATSUMOTO, Mitsuke-shi (JP); Masahiro ICHIHARA, Mitsuke-shi (JP)

(21) Appl. No.: 15/321,791

(22) PCT Filed: Jun. 19, 2015
(86) PCT No.: PCT/JP2015/067675

§ 371 Date: Dec. 23, 2016

(30) Foreign Application Priority Data
Jun. 26, 2014 (JP) 2014-131796

(51) Int. Cl. C23C 14/04; H01L 51/00; C23C 14/24

(52) U.S. Cl. CPC C23C 14/042; C23C 14/24; H01L 51/001; H01L 51/0011

(57) ABSTRACT

The present invention provides a mask for production of an organic EL element, an apparatus for producing an organic EL element, and a method for producing an organic EL element which can give reduced luminance unevenness and eased restrictions in the production apparatus. The mask of the present invention includes first to fourth opening regions arranged in a staggered pattern, the first, second, third, and fourth opening regions arranged in the given order in a first direction, the first, second, third, and fourth opening regions respectively including first, second, third, and fourth mask openings in a second direction perpendicular to the first direction, the mask including no mask openings on the side of the first opening region opposite to the third opening region, the first and second mask openings each having a shorter length in the first direction than each of the third and fourth mask openings.

### TECHNICAL FIELD

The present invention relates to masks for production of an organic electroluminescent (hereinafter, also abbreviated as EL) element, apparatuses for producing an organic EL element, and methods for producing an organic EL element. The present invention more specifically relates to a mask for production of an organic EL element, an apparatus for producing an organic EL element, and a method for producing an organic EL element which are suitable for production of an organic EL element to be disposed on a large substrate.

### BACKGROUND ART

Flat panel displays have been utilized in various products and fields, and are demanded to have a further increased size and higher display quality and to achieve lower power consumption.

The demand has brought much attention to use of organic EL devices provided with organic EL elements utilizing electroluminescence of organic materials as display devices for flat panel displays which are in the all-solid state and excellent in properties such as low power consumption, high response speed, and self-luminescence.

Organic EL devices include, for example, thin film transistors (TFTs) and organic EL elements connected to the respective TFTs on a substrate such as a glass substrate. Each organic EL element has a structure in which a first electrode, an organic EL layer, and a second electrode are stacked in the given order. In the organic EL element, the first electrode is the component connected to the corresponding TFT. The organic EL layer has a structure in which layers such as a hole injection layer, a hole transport layer, an electron-blocking layer, a light-emitting layer, a hole-blocking layer, an electron transport layer, and an electron injection layer are stacked.

Organic EL devices providing full-color display typically include organic EL elements of three colors, namely red (R), green (G), and blue (B), as sub-pixels. The sub-pixels are arranged in a matrix, and a group of sub-pixels of the respective three colors constitutes one pixel. The devices selectively cause the organic EL elements to emit light with the desired luminance so as to provide image display.

In production of such an organic EL device, the light-emitting layer formed from a luminescent material is patterned correspondingly to the organic EL elements (sub-pixels) of the individual colors.

Developed methods for patterning a light-emitting layer include a method of performing vapor deposition on a substrate, with a mask of substantially the same size as the substrate being in contact with the substrate (hereinafter, this method is also referred to as a contact film-formation method), and a method of performing vapor deposition on the entire substrate with a mask smaller than the substrate while moving (scanning) the substrate relatively to the mask and a vapor-deposition source (hereinafter, this method is also referred to as a scanning film-formation method). Examples of disclosed techniques for the scanning film-formation method are as described below.

Patent Literature 1, for example, discloses a vapor deposition apparatus wherein a mask unit, which comprises a shadow mask that has an opening portion and an area smaller than that of a vapor deposition region of a substrate on which a film is formed and a vapor deposition source that has an ejection port for ejecting vapor deposition particles such that the ejection port faces the shadow mask with the relative positions of the shadow mask and the vapor deposition source being fixed, is used, and the vapor deposition particles are sequentially deposited on the vapor deposition region through the opening portion of the shadow mask by relatively moving at least one of the mask unit and the substrate, while adjusting the gap between the shadow mask and the substrate so that the gap between the mask unit and the substrate becomes constant.

Patent Literature 2, for example, discloses a manufacturing method for an organic EL element including a coating film having a predetermined pattern on a substrate, the method comprising: a vapor deposition step of forming the coating film by causing vapor deposition particles to adhere to the substrate, wherein the vapor deposition step is a step in which with the use of a vapor deposition unit including a vapor deposition source having a vapor deposition source opening that discharges the vapor deposition particles and a vapor deposition mask disposed between the vapor deposition source opening and the substrate, in a state in which the substrate and the vapor deposition mask are spaced apart at a fixed interval, the vapor deposition particles that have passed through a plurality of mask openings formed in the vapor deposition mask are caused to adhere to the substrate while one of the substrate and the vapor deposition unit is moved relative to the other, when a relative movement direction between the substrate and the vapor deposition unit is defined as a first direction and a direction orthogonal to the first direction is defined as a second direction, the vapor deposition unit includes, between the vapor deposition source opening and the vapor deposition mask, a plurality of limiting plates whose positions in the second direction are different, and each of the plurality of limiting plates limits an incidence angle of the vapor deposition particles entering the respective mask openings, as viewed in the first direction.

### CITATION LIST

### Patent Literature

Patent Literature 1: WO 2011/034011
Patent Literature 2: WO 2011/145456

### SUMMARY OF INVENTION

### Technical Problem

Organic EL devices produced by the scanning film-formation method, however, may regularly cause stripe luminance unevenness (hereinafter, also referred to as stitching unevenness) in the entire display region, leading to poor light emission.

The causes of stitching unevenness are now described with reference to an example, which is an apparatus for producing an organic EL element according to Comparative Embodiment 1 on which the inventors made studies. For description below, a Cartesian coordinate system may appropriately be used in which the X-axis and Y-axis are present in the horizontal plane and the Z-axis extends in the vertical direction.

FIG. 20 is a schematic perspective view of an apparatus for producing an organic EL element according to Comparative Embodiment 1 on which the inventors made studies.

As illustrated in FIG. 20, an apparatus for producing an organic EL element according to Comparative Embodiment 1 is a vacuum vapor-deposition apparatus utilizing the scanning film-formation method, and includes a vapor-deposition chamber (vacuum chamber, not illustrated); a vapor-deposition unit 1153 disposed in the vapor-deposition chamber; and a transfer mechanism (not illustrated) configured to transfer a substrate 1190 for an organic EL display device (the vapor-deposition target). The vapor-deposition unit 1153 includes a vapor-deposition source 1160 with nozzles 1162; a limiting plate 1170 that includes openings 1171 formed correspondingly to the nozzles 1162 and is configured to define the scattering range for vapor-deposition particles (vaporized material) ejected from the nozzles 1162; and a mask 1100 for production of an organic EL element that includes opening regions 1101 each provided with mask openings (through holes) 1102 for patterning. The apparatus performs vapor deposition of vapor-deposition particles on the substrate 1190 via the mask 1100 while transferring with the transfer mechanism the substrate 1190 in the Y-axial direction above the mask 1100. In the substrate 1190, a hole transport layer is formed to cover every pixel, and a light-emitting layer material is used as the vapor-deposition material. The apparatus can therefore pattern the light-emitting layer on the hole transport layer in a pattern corresponding to the pattern of the mask openings 1102, i.e., in a stripe pattern.

The adjacent opening regions 1101 are spaced from each other at approximately the same distance as the width in the X-axial direction of the opening regions 1101. With this structure, the apparatus fails to pattern the entire vapor-deposition target region just by one-time transfer of the substrate 1190. Therefore, in the present comparative embodiment, the apparatus forms a first patterned light-emitting layer on substantially the half of the vapor-deposition target region just by one-time transfer of the substrate 1190, moves the vapor-deposition unit 1153 or the substrate 1190 in the X-axial direction to cause the opening regions 1101 to face the non-patterned region, and then forms a second patterned light-emitting layer on substantially the other half of the vapor-deposition target region by transferring the substrate 1190 again.

In the vapor-deposition chamber, contaminants are brought by members (e.g., transfer mechanism), and the contaminants adhere to the surface of the substrate 1190 from transfer of the substrate 1190 into the vapor-deposition chamber to transfer out. Examples of the contaminants include grease components scattered from the members.

In Comparative Embodiment 1, as described above, after the first patterned light-emitting layer is formed and the vapor-deposition unit 1153 or the substrate 1190 is moved in the X-axial direction, the second patterned light-emitting layer is formed. This process results in a larger amount of adhering contaminants in the region in which the second patterned light-emitting layer is formed than in the region in which the first patterned light-emitting layer is formed, so that the region in which the second patterned light-emitting layer is formed has lower luminance than the region in which the first patterned light-emitting layer is formed. This luminance difference between the regions appears as stitching unevenness. That is, the cause of stitching unevenness is considered to be the difference in time before the start of vapor deposition between these regions.

Here, a method may also be possible in which mask openings are uniformly formed in a mask for production of an organic EL element so that a patterned light-emitting layer is formed on the entire vapor-deposition target region just by one-time transfer of the substrate. Comparative Embodiment 1, however, requires transfer of the substrate 1190 multiple times for patterning because there are restrictions in the production apparatus, such as the pitch of the nozzles 1162 and the distance between the vapor-deposition source 1160 and the substrate 1190 (hereinafter, this distance is also referred to as T/S). For example, with a short T/S, the flows of the vapor-deposition particles (hereinafter, also referred to as vapor-deposition streams) are highly oriented, so that the widths of vapor-deposition streams are narrow. Narrow widths of vapor-deposition streams bring the need for arranging the nozzles 1162 at a narrow pitch for patterning of the entire vapor-deposition target region of the substrate 1190 just by one-time transfer. However, arranging the nozzles 1162 at a narrow pitch may increase the density of vapor-deposition particles in the vicinities of the nozzles 1162. The high density increases the scattering intensity of vapor-deposition particles, and thereby results in defects such as blurring. Here, the blurring means, in a formed film (vapor-deposition film), gradual thinning of a side part formed on each side of the middle part whose thickness is constant.

FIG. 21 is a perspective plan view from the vapor-deposition mask side of a vapor-deposition block in an apparatus for producing an organic EL element described in Patent Literature 2.

As illustrated in FIG. 21, in an apparatus for producing an organic EL element illustrated in FIG. 17 of Patent Literature 2, vapor-deposition source openings 1261 of a vapor-deposition source 1260 are arranged in two lines in a staggered pattern. The apparatus includes vapor-deposition blocks 1251 arranged in a staggered pattern, and each of the vapor-deposition blocks 1251 is formed by paired limiting plates 1281 adjacent in the X-axial direction, one vapor-deposition source opening 1261 arranged between the paired limiting plates 1281, and mask openings 1271 arranged between the paired limiting plates 1281. This configuration gives a higher degree of freedom to the design of the apparatus, allowing formation of a patterned light-emitting layer on the entire vapor-deposition target region just by one-time transfer of the substrate.

Still, during vapor deposition performed by the vapor-deposition blocks 1251 in the line I, the region for which vapor deposition is to be performed by the vapor-deposition blocks 1251 in the line II is exposed to contaminants, meaning that more contaminants adhere to this region than to the region for which vapor deposition is performed by the vapor-deposition blocks 1251 in the line I. Accordingly, the region for which vapor deposition is performed by the vapor-deposition blocks 1251 in the line II includes more contaminants than the region for which vapor deposition is performed by the vapor-deposition blocks 1251 in the line I, whereby stitching unevenness occurs.

As described above, use of the scanning film-formation method can still be improved in terms of ease of restrictions in the production apparatus and reduction of luminance unevenness.

The present invention has been made in view of the above current state of the art, and aims to provide a mask for production of an organic EL element, an apparatus for producing an organic EL element, and a method for producing an organic EL element which can give reduced luminance unevenness and eased restrictions in production apparatuses.

### Solution to Problem

One aspect of the present invention may be a mask for production of an organic electroluminescent element, including

a patterning portion including mask openings for patterning,

the patterning portion including first to fourth opening regions arranged in a staggered pattern,

the first, second, third, and fourth opening regions being arranged in the given order in a first direction that is parallel to the patterning portion,

the first opening region, the second opening region, the third opening region, and the fourth opening region respectively including first mask openings, second mask openings, third mask openings, and fourth mask openings in a second direction that is parallel to the patterning portion and perpendicular to the first direction,

the third mask openings being arranged correspondingly to the first mask openings,

each of the first mask openings and the third mask opening corresponding to the first mask opening being on the same straight line that is parallel to the first direction,

the fourth mask openings being arranged correspondingly to the second mask openings,

each of the second mask openings and the fourth mask opening corresponding to the second mask opening being on the same straight line that is parallel to the first direction,

the mask including no mask openings on the side of the first opening region opposite to the third opening region,

the first mask openings and the second mask openings each having a shorter length in the first direction than each of the third mask openings and fourth mask openings.

Hereinafter, such a mask for production of an organic EL element is also referred to as the mask of the present invention.

Another aspect of the present invention may be an apparatus for producing an organic electroluminescent element through formation of a film on a substrate, including:

the mask of the present invention;

a vapor-deposition unit including a vapor-deposition source configured to eject vapor-deposition particles; and

a transfer mechanism configured to move the substrate relatively to the vapor-deposition unit in the first direction, with the substrate being away from the mask of the present invention,

the mask of the present invention being disposed such that the first, second, third, and fourth opening regions face the substrate in the given order or the fourth, third, second, and first opening regions face the substrate in the given order.

Hereinafter, such an apparatus for producing an organic EL element is also referred to as the production apparatus of the present invention.

Yet another aspect of the present invention may be a method for producing an organic electroluminescent element with use of a mask for production of an organic electroluminescent element,

the mask for production of an organic electroluminescent element including a patterning portion including mask openings for patterning,

the patterning portion including first to fourth opening regions arranged in a staggered pattern,

the first, second, third, and fourth opening regions being arranged in the given order in a first direction that is parallel to the patterning portion,

the first opening region, the second opening region, the third opening region, and the fourth opening region respectively including first mask openings, second mask openings, third mask openings, and fourth mask openings in a second direction that is parallel to the patterning portion and perpendicular to the first direction,

the third mask openings being arranged correspondingly to the first mask openings,

each of the first mask openings and the third mask opening corresponding to the first mask opening being on the same straight line that is parallel to the first direction,

the fourth mask openings being arranged correspondingly to the second mask openings,

each of the second mask openings and the fourth mask opening corresponding to the second mask opening being on the same straight line that is parallel to the first direction,

the mask including no mask openings on the side of the first opening region opposite to the third opening region,

the first mask openings and the second mask openings each having a shorter length in the first direction than each of the third mask openings and fourth mask openings,

the production method including:

a vapor-deposition step of causing vapor-deposition particles to adhere to the substrate via the mask for production of an organic electroluminescent element while moving in the first direction the substrate relatively to a vapor-deposition unit including the mask for production of an organic electroluminescent element and a vapor-deposition source configured to eject vapor-deposition particles, with the substrate being away from the mask for production of an organic electroluminescent element,

the mask for production of an organic electroluminescent element, in the vapor-deposition step, being disposed such that the first, second, third, and fourth opening regions face the substrate in the given order or the fourth, third, second, and first opening regions face the substrate in the given order.

Hereinafter, such a method for producing an organic EL element is also referred to as the production method of the present invention.

The case of “moving something (e.g., substrate) in some direction (e.g., first direction)” as used herein includes moving the thing in the given direction and moving the thing in the direction opposite to the given direction. Hence, for example, in the production apparatus of the present invention, the transfer mechanism may move the substrate relatively to the vapor-deposition unit in the first direction (positive direction of an axis), and may move the substrate relatively to the vapor-deposition unit in the direction (negative direction of the axis) opposite to the first direction.

Preferred embodiments of the mask of the present invention, the production apparatus of the present invention, and the production method of the present invention are described below. The preferred embodiments below may appropriately be combined with each other. An embodiment obtained by combining two or more of the preferred embodiments below is also a preferred embodiment.

The mask may be a mask wherein the first mask openings and the second mask openings have substantially the same length in the first direction.

The mask may be a mask wherein the patterning portion further includes fifth and sixth opening regions,

the first to sixth opening regions are arranged in a staggered pattern,

the first, second, fifth, sixth, third, and fourth opening regions are arranged in the given order in the first direction,

the fifth opening region and the sixth opening region respectively include fifth mask openings and sixth mask openings in the second direction,

the fifth mask openings are arranged correspondingly to the first mask openings and the third mask openings,

each of the first mask openings and the fifth mask opening and third mask opening corresponding to the first mask opening are on the same straight line that is parallel to the first direction,

the sixth mask openings are arranged correspondingly to the second mask openings and the fourth mask openings,

each of the second mask openings and the sixth mask opening and fourth mask opening corresponding to the second mask opening are on the same straight line that is parallel to the first direction, and

the fifth mask openings and the sixth mask openings each have a shorter length in the first direction than each of the third mask openings and fourth mask openings.

The mask may be a mask wherein the patterning portion further includes fifth and sixth opening regions,

the first to sixth opening regions are arranged in a staggered pattern,

the first, second, third, fourth, fifth, and sixth opening regions are arranged in the given order in the first direction,

the fifth opening region and the sixth opening region respectively include fifth mask openings and sixth mask openings in the second direction,

the fifth mask openings are arranged correspondingly to the first mask openings and the third mask openings,

each of the first mask openings and the fifth mask opening and third mask opening corresponding to the first mask opening are on the same straight line that is parallel to the first direction,

the sixth mask openings are arranged correspondingly to the second mask openings and the fourth mask openings,

each of the second mask openings and the sixth mask opening and fourth mask opening corresponding to the second mask opening are on the same straight line that is parallel to the first direction, and

the fifth mask openings and the sixth mask openings each have a shorter length in the first direction than each of the third mask openings and fourth mask openings.

The mask may be a mask wherein the fifth mask openings and the sixth mask openings have substantially the same length in the first direction.

The production apparatus and the production method of the present invention may respectively be a production apparatus and a production method wherein the vapor-deposition source may include first, second, third, and fourth orifices respectively corresponding to the first, second, third, and fourth opening regions.

The production apparatus and the production method of the present invention may respectively be a production apparatus and a production method wherein the vapor-deposition source includes a first orifice corresponding to the first and third opening regions, and a second orifice corresponding to the second and fourth opening regions.

The production apparatus and the production method of the present invention may respectively be a production apparatus and a production method wherein the first orifice is positioned at the center between a center portion of the first opening region and a center portion of the third opening region as viewed from a third direction that is perpendicular to the first direction and the second direction, and

the second orifice is positioned at the center between a center portion of the second opening region and a center portion of the fourth opening region as viewed from the third direction.

The production apparatus of the present invention may be a production apparatus further including a limiting plate disposed between the mask of the present invention and the vapor-deposition source,

wherein the limiting plate includes first, second, third, and fourth openings respectively corresponding to the first, second, third, and fourth opening regions.

In the above vapor-deposition step, a limiting plate including first, second, third, and fourth openings respectively corresponding to the first, second, third, and fourth opening regions may be disposed between the mask for production of an organic electroluminescent element and the vapor-deposition source.

The production apparatus of the present invention may be a production apparatus further including additional limiting plates disposed between the mask of the present invention and the limiting plate,

wherein the additional limiting plates separate a space between the mask of the present invention and the limiting plate into four spaces respectively corresponding to the first, second, third, and fourth opening regions.

In the above vapor-deposition step, additional limiting plates separating a space between the mask for production of an organic electroluminescent element and the limiting plate into four spaces respectively corresponding to the first, second, third, and fourth opening regions may be disposed between the mask for production of an organic electroluminescent element and the limiting plate.

### Advantageous Effects of Invention

The present invention can provide a mask for production of an organic EL element, an apparatus for producing an organic EL element, and a method for producing an organic EL element which can give reduced luminance unevenness and eased restrictions in the production apparatus.

### BRIEF DESCRIPTION OF DRAWINGS

FIG. 1 is a schematic cross-sectional view of an organic EL display device including an organic EL element produced by a method for producing an organic EL element according to Embodiment 1.

FIG. 2 is a schematic plan view of the configuration of a display region in the organic EL display device illustrated in FIG. 1.

FIG. 3 is a schematic cross-sectional view of the configuration of a TFT substrate in the organic EL display device illustrated in FIG. 1, corresponding to the cross section taken along the A-B line illustrated in FIG. 2.

FIG. 4 is a flowchart for describing the steps of producing an organic EL element and an organic EL display device according to Embodiment 1.

FIG. 5 is a schematic plan view of a mask for production of an organic EL element according to Embodiment 1.

FIG. 6 is a schematic plan view of the mask for production of an organic EL element according to Embodiment 1, illustrating one opening block in an enlarged view.

FIG. 7 is a schematic perspective view of an apparatus for producing an organic EL element according to Embodiment 1.

FIG. 8 is a schematic plan view of the apparatus for producing an organic EL element according to Embodiment 1.

FIG. 9 is a schematic cross-sectional view of the apparatus for producing an organic EL element according to Embodiment 1, illustrating a cross section perpendicular to the Y-axial direction.

FIG. 10 is a schematic plan view of an apparatus for producing an organic EL element according to Embodiment 2.

FIG. 11 is a schematic perspective view of the apparatus for producing an organic EL element according to Embodiment 2.

FIG. 12 is a schematic cross-sectional view of the apparatus for producing an organic EL element according to Embodiment 2, illustrating a cross section perpendicular to the Y-axial direction.

FIG. 13 is a schematic perspective view of an apparatus for producing an organic EL element according to Embodiment 3.

FIG. 14 is a schematic plan view of the apparatus for producing an organic EL element according to Embodiment 3.

FIG. 15 is a schematic plan view of a mask for production of an organic EL element according to Embodiment 4.

FIG. 16 is a schematic plan view of the mask for production of an organic EL element according to Embodiment 4, illustrating one opening block in an enlarged view.

FIG. 17 is a schematic plan view of a mask for production of an organic EL element according to Embodiment 5.

FIG. 18 is a schematic plan view of the mask for production of an organic EL element according to Embodiment 5, illustrating one opening block in an enlarged view.

FIG. 19 is a schematic plan view of a mask for production of an organic EL element according to Embodiment 6.

FIG. 20 is a schematic perspective view of an apparatus for producing an organic EL element according to Comparative Embodiment 1 on which the inventors made studies.

FIG. 21 is a perspective plan view from the vapor-deposition mask side of a vapor-deposition block in an apparatus for producing an organic EL element described in Patent Literature 2.

FIG. 22 is a schematic plan view of a mask for production of an organic EL element according to Comparative Embodiment 2 on which the inventors made studies.

### DESCRIPTION OF EMBODIMENTS

The present invention is further described based on embodiments below with reference to the drawings. The present invention, however, is not limited to these embodiments.

For description of the following embodiments, a Cartesian coordinate system may appropriately be used in which the X-axis and Y-axis are present in the horizontal plane and the Z-axis extends in the vertical direction. Also in the following embodiments, the X-axial direction, Y-axial direction, and Z-axial direction respectively correspond to the second direction, first direction, and third direction in the mask of the present invention and the production apparatus of the present invention.

### Embodiment 1

Mainly described in the present embodiment are an apparatus and a method for producing an organic EL element for an organic EL display device that is of the bottom-emission type emitting light from the TFT substrate side and provides RGB full-color display; and an organic EL display device including organic EL elements produced by the production apparatus or production method. Still, the present embodiment is applicable to methods for producing organic EL elements of the other types.

First, the overall configuration of the organic EL display device of the present embodiment is described.

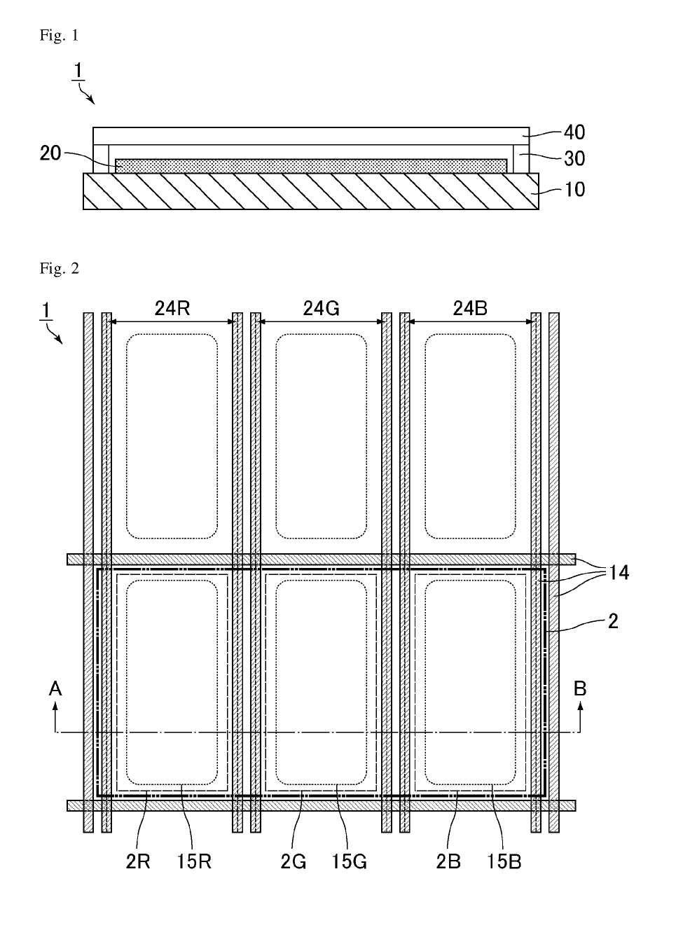

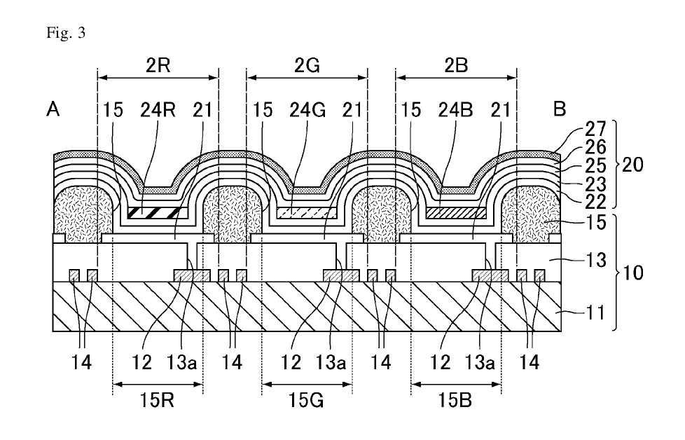

FIG. 1 is a schematic cross-sectional view of an organic EL display device including an organic EL element produced by a method for producing an organic EL element according to Embodiment 1. FIG. 2 is a schematic plan view of the configuration of a display region in the organic EL display device illustrated in FIG. 1. FIG. 3 is a schematic cross-sectional view of the configuration of a TFT substrate in the organic EL display device illustrated in FIG. 1, corresponding to the A-B line illustrated in FIG. 2.

As illustrated in FIG. 1, an organic EL display device 1 of the present embodiment includes a TFT substrate 10 provided with TFTs 12 (FIG. 3), organic EL elements 20 that are provided on the TFT substrate 10 and connected to the respective TFTs 12, an adhesive layer 30 disposed to surround the organic EL elements 20 in a frame shape, and a sealing substrate 40 disposed to cover the organic EL elements 20. With the adhesive layer 30, the peripheral portion of the TFT substrate 10 and the peripheral portion of the sealing substrate 40 are attached to each other.

Since the sealing substrate 40 and the TFT substrate 10 with the organic EL elements 20 stacked thereon are attached with the adhesive layer 30, the organic EL elements 20 are sealed between the substrates 10 and 40 constituting one pair. Thereby, oxygen and moisture in the outside air are prevented from entering the organic EL elements 20.

As illustrated in FIG. 3, the TFT substrate 10 includes a transparent insulating substrate 11 (e.g., glass substrate) as a supporting substrate. As illustrated in FIG. 2, conductive lines 14 are formed on the insulating substrate 11, and include gate lines that are provided in the horizontal direction (length direction) and signal lines that are provided in the vertical direction (width direction) and cross the gate lines. The gate lines are connected to a gate-line drive circuit (not illustrated) configured to drive the gate lines. The signal lines are connected to a signal-line drive circuit (not illustrated) configured to drive the signal lines.

The organic EL display device 1 is an active-matrix display device providing RGB full-color display, and each region defined by the conductive lines 14 includes a sub-pixel (dot) 2R, 2G, or 2B in a color red (R), green (G), or blue (B). The sub-pixels 2R, 2G, and 2B are arranged in a matrix. In each of the sub-pixels 2R, 2G, and 2B in the respective colors, an organic EL element 20 of the corresponding color and a light-emitting region are formed.

The red, green, and blue sub-pixels 2R, 2G, and 2B respectively emit red light, green light, and blue light, and each group of the three sub-pixels 2R, 2G, and 2B form one pixel 2.

The sub-pixels 2R, 2G, and 2B are respectively provided with openings 15R, 15G, and 15B, and the openings 15R, 15G, and 15B are covered with red, green, and blue light-emitting layers 24R, 24G, and 24B, respectively. The light-emitting layers 24R, 24G, and 24B form stripes in the vertical direction (length direction). The patterned light-emitting layers 24R, 24G, and 24B are formed separately for one color at one time by vapor deposition. The openings 15R, 15G, and 15B are described later.

Each of the sub-pixels 2R, 2G, and 2B is provided with a TFT 12 connected to a first electrode 21 of the organic EL element 20. The luminescence intensity of each of the sub-pixels 2R, 2G, and 2B is determined based on scanning and selection using the conductive lines 14 and the TFTs 12. As described above, the organic EL display device 1 provides image display by selectively allowing the organic EL elements 20 in the individual colors to emit light, using the TFTs 12.

Next, the configurations of the TFT substrate 10 and the organic EL elements 20 are described in detail. First, the TFT substrate 10 is described.

As illustrated in FIG. 3, the TFT substrate 10 is provided with the TFTs 12 (switching elements) and the conductive lines 14 which are formed on the insulating substrate 11; an interlayer film (interlayer insulating film, flattening film) 13 that covers the TFTs and conductive lines; and an edge cover 15 which is an insulating layer formed on the interlayer film 13.

The TFTs 12 are formed for the respective sub-pixels 2R, 2G, and 2B. Here, since the configuration of the TFTs 12 may be a common configuration, layers in the TFTs 12 are not illustrated or described.

The interlayer film 13 is formed on the insulating substrate 11 to cover the entire region of the insulating substrate 11. On the interlayer film 13, the first electrodes 21 of the organic EL elements 20 are formed. Also, the interlayer film 13 is provided with contact holes 13a for electrically connecting the first electrodes 21 to the TFTs 12. In this manner, the TFTs 12 are electrically connected to the organic EL elements 20 via the contact holes 13a.

The edge cover 15 is formed to prevent a short circuit between the first electrode 21 and a second electrode 27 of each organic EL element 20 when the organic EL layer is thin or concentration of electric fields occurs at the end of the first electrode 21. The edge cover 15 is therefore formed to partly cover the ends of the first electrodes 21.

The above-mentioned openings 15R, 15G, and 15B are formed in the edge cover 15. These openings 15R, 15G, and 15B of the edge cover 15 respectively serve as light-emitting regions of the sub-pixels 2R, 2G, and 2B. In other words, the sub-pixels 2R, 2G, and 2B are separated by the edge cover 15 which has insulation properties. The edge cover 15 functions also as an element-separation film.

Next, the organic EL elements 20 are described.

The organic EL elements 20 are light-emitting elements capable of providing high-luminance light when driven by direct current, and each include the first electrode 21, the organic EL layer, and the second electrode 27 which are stacked in the given order.

The first electrode 21 is a layer having a function of injecting (supplying) holes into the organic EL layer. The first electrode 21 is connected to the TFT 12 via the contact hole 13a as described above.

As illustrated in FIG. 3, the organic EL layer between the first electrode 21 and the second electrode 27 includes a hole injection layer 22, a hole transport layer 23, the light-emitting layer 24R, 24G, or 24B, an electron transport layer 25, and an electron injection layer 26 in the given order from the first electrode 21 side.

The above stacking order is for the case that the first electrode 21 is an anode and the second electrode 27 is a cathode. In the case that the first electrode 21 is a cathode and the second electrode 27 is an anode, the stacking order for the organic EL layer is reversed.

The hole injection layer 22 has a function of increasing the hole injection efficiency to the light-emitting layer 24R, 24G, or 24B. The hole transport layer 23 has a function of increasing the hole transport efficiency to the light-emitting layer 24R, 24G, or 24B. The hole injection layer 22 is uniformly formed on the entire display region of the TFT substrate 10 to cover the first electrodes 21 and the edge cover 15. The hole transport layer 23 is uniformly formed on the entire display region of the TFT substrate 10 to cover the hole injection layer 22.

The hole injection layer 22 and the hole transport layer 23 may be formed as layers independent of each other as described above or may be integrated. That is, the organic EL display device 1 may include a hole injection/hole transport layer in place of the hole injection layer 22 and the hole transport layer 23. The hole injection/hole transport layer has both the function of a hole injection layer and the function of a hole transport layer.

On the hole transport layer 23, the light-emitting layers 24R, 24G, and 24B are formed correspondingly to, respectively, sub-pixels 2R, 2G, and 2B, to cover the openings 15R, 15G, and 15B of the edge cover 15.

Each of the light-emitting layers 24R, 24G, and 24B has a function of emitting light by recombining holes injected from the first electrode 21 side and electrons injected from the second electrode 27 side. Each of the light-emitting layers 24R, 24G, and 24B is formed from a material exhibiting a high luminous efficiency, such as a low-molecular fluorescent dye or a metal complex.

The electron transport layer 25 has a function of increasing the electron transport efficiency from the second electrode 27 to each of the light-emitting layers 24R, 24G, and 24B. The electron injection layer 26 has a function of increasing the electron injection efficiency from the second electrode 27 to each of the light-emitting layers 24R, 24G, and 24B.

The electron transport layer 25 is uniformly formed on the entire display region of the TFT substrate 10 to cover the light-emitting layers 24R, 24G, and 24B, and the hole transport layer 23. Also, the electron injection layer 26 is uniformly formed on the entire display region of the TFT substrate 10 to cover the electron transport layer 25.

The electron transport layer 25 and the electron injection layer 26 may be formed as layers independent of each other as described above or may be integrated. That is, the organic EL display device 1 may include an electron transport/electron injection layer in place of the electron transport layer 25 and the electron injection layer 26. The electron transport/electron injection layer has both the function of an electron injection layer and the function of an electron transport layer.

The second electrode 27 has a function of injecting electrons to the organic EL layer. The second electrode 27 is uniformly formed on the entire display region of the TFT substrate 10 to cover the electron injection layer 26.

Here, organic layers other than the light-emitting layers 24R, 24G, and 24B are not essential layers for the organic EL layer, and may be appropriately formed depending on the required properties of the organic EL elements 20. The organic EL layer may additionally include a carrier-blocking layer. For example, a hole-blocking layer may be added as a carrier-blocking layer between the light-emitting layer 24R, 24G, or 24B and the electron transport layer 25 such that holes can be prevented from reaching the electron transport layer 25, and thereby the light-emitting efficiency is enhanced.

The configuration of the organic EL elements 20 may be any of the following layer configurations (1) to (8).

(1) First electrode/light-emitting layer/second electrode

(2) First electrode/hole transport layer/light-emitting layer/electron transport layer/second electrode

(3) First electrode/hole transport layer/light-emitting layer/hole-blocking layer/electron transport layer/second electrode

(4) First electrode/hole transport layer/light-emitting layer/hole-blocking layer/electron transport layer/electron injection layer/second electrode

(5) First electrode/hole injection layer/hole transport layer/light-emitting layer/electron transport layer/electron injection layer/second electrode

(6) First electrode/hole injection layer/hole transport layer/light-emitting layer/hole-blocking layer/electron transport layer/second electrode

(7) First electrode/hole injection layer/hole transport layer/light-emitting layer/hole-blocking layer/electron transport layer/electron injection layer/second electrode

(8) First electrode/hole injection layer/hole transport layer/electron-blocking layer (carrier-blocking layer)/light-emitting layer/hole-blocking layer/electron transport layer/electron injection layer/second electrode

The hole injection layer and the hole transport layer may be integrated as described above. Also, the electron transport layer and the electron injection layer may be integrated.

The configuration of the organic EL elements 20 is not particularly limited to the layer configurations (1) to (8), and any desired layer configuration can be used depending on the required properties of the organic EL elements 20.

Next, the method for producing the organic EL elements 20 and the organic EL display device 1 is described.

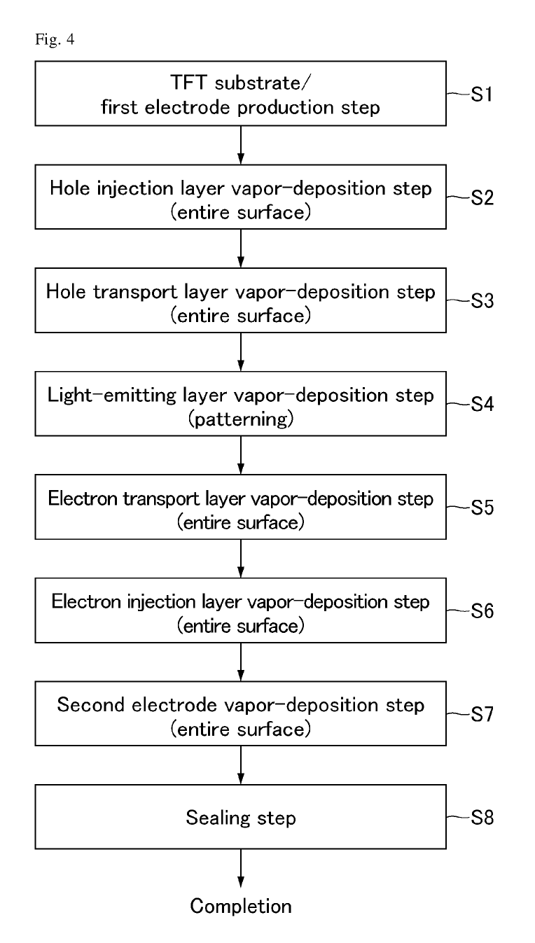

FIG. 4 is a flowchart for describing the steps of producing an organic EL element and an organic EL display device according to Embodiment 1.

As illustrated in FIG. 4, the method for producing an organic EL element and an organic EL display device according to the present embodiment includes, for example, a TFT substrate/first electrode production step S1, a hole injection layer vapor-deposition step S2, a hole transport layer vapor-deposition step S3, a light-emitting layer vapor-deposition step S4, an electron transport layer vapor-deposition step S5, an electron injection layer vapor-deposition step S6, a second electrode vapor-deposition step S7, and a sealing step S8.

The light-emitting layer vapor-deposition step S4 is usually performed by an in-line method, but may be performed by a multi-chamber method. The other vapor-deposition steps may be performed by the in-line method or the multi-chamber method.

Hereinafter, the production steps of the components described above with reference to FIGS. 1 to 3 are described by following the flowchart shown in FIG. 4. The size, material, shape, and the other designs of each component described in the present embodiment are merely examples which are not intended to limit the scope of the present invention.

As described above, the stacking order described in the present embodiment is for the case that the first electrode 21 is an anode and the second electrode 27 is a cathode. In the case that the first electrode 21 is a cathode and the second electrode 27 is an anode, the stacking order for the organic EL layer is reversed. Similarly, the materials of the first electrode 21 and the second electrode 27 are changed to the corresponding materials.

First, as illustrated in FIG. 3, a photosensitive resin is applied to the insulating substrate 11 on which components such as the TFTs 12 and the conductive lines 14 are formed by a common method, and the photosensitive resin is patterned by photolithography, so that the interlayer film 13 is formed on the insulating substrate 11.

The insulating substrate 11 may be, for example, a glass substrate or a plastic substrate with a thickness of 0.7 to 1.1 mm, a Y-axial direction length (vertical length) of 400 to 500 mm, and an X-axial direction length (horizontal length) of 300 to 400 mm.

The material of the interlayer film 13 can be, for example, a resin such as an acrylic resin or a polyimide resin. Examples of the acrylic resin include the OPTMER series from JSR Corporation. Examples of the polyimide resin include the PHOTONEECE series from Toray Industries, Inc. The polyimide resin, however, is typically colored and not transparent. For this reason, in the case of producing a bottom-emission organic EL display device as the organic EL display device 1 as illustrated in FIG. 3, a transparent resin such as an acrylic resin is more suitable for the interlayer film 13.

The thickness of the interlayer film 13 may be any value that can compensate for the height differences formed by the TFTs 12 and gives a flat surface to the interlayer film 13. For example, the thickness may be about 2 μm.

Next, the contact holes 13a for electrically connecting the first electrodes 21 to the TFTs 12 are formed in the interlayer film 13.

A conductive film (electrode film), for example an indium tin oxide (ITO) film, is formed to a thickness of 100 nm by sputtering or the like method.

A photoresist is applied to the ITO film, and the photoresist is patterned by photolithography. Then, the ITO film is etched with ferric chloride which is used as an etching solution. The photoresist is removed by a resist removing solution, and the substrate is washed. Thereby, the first electrodes 21 are formed in a matrix on the interlayer film 13.

The conductive film material used for the first electrodes 21 may be, for example, a transparent conductive material such as ITO, indium zinc oxide (IZO), or gallium-added zinc oxide (GZO); or a metal material such as gold (Au), nickel (Ni), or platinum (Pt).

The stacking method for the conductive film other than sputtering may be vacuum vapor deposition, chemical vapor deposition (CVD), plasma CVD, or printing, for example.

The thickness of each first electrode 21 is not particularly limited, and may be 100 nm as described above, for example.

The edge cover 15 is then formed to a thickness of about 1 μm, for example, by the same method as that for the interlayer film 13. The material of the edge cover 15 can be the same insulating material as that of the interlayer film 13.

By the above procedure, the TFT substrate 10 and the first electrodes 21 are produced (S1).

Next, the TFT substrate 10 obtained in the above step is subjected to the reduced-pressure baking for dehydration, and to oxygen plasma treatment for surface washing of the first electrodes 21.

With a common vapor deposition apparatus, a hole injection layer 22 is vapor-deposited on the entire display region of the TFT substrate 10 (S2).

Specifically, an open mask which is open to the entire display region is subjected to alignment control relative to the TFT substrate 10, and the open mask is attached closely to the TFT substrate 10. The vapor-deposition particles dispersed from the vapor deposition source are then uniformly vapor-deposited on the entire display region via the openings of the open mask, while both the TFT substrate 10 and the open mask are rotated.

Here, the vapor deposition on the entire display region means continuous vapor deposition over sub-pixels which are in different colors from the adjacent sub-pixels.

Subsequently, by the same method as in the hole injection layer vapor-deposition step S2, the hole transport layer 23 is vapor-deposited on the entire display region of the TFT substrate 10 to cover the hole injection layer 22 (S3).

Examples of the material of the hole injection layer 22 and the hole transport layer 23 include, but are not particularly limited to, benzine, styrylamine, triphenylamine, porphyrin, triazole, imidazole, oxadiazole, polyarylalkane, phenylenediamine, arylamine, oxazole, anthracene, fluorenone, hydrazone, stilbene, triphenylene, azatriphenylene, and derivatives thereof; polysilane-based compounds; vinylcarbazole-based compounds; and conjugated heterocyclic monomers, oligomers, or polymers, such as thiophene-based compounds and aniline-based compounds.

The hole injection layer 22 and the hole transport layer 23 may be integrated as described above, or may be formed as layers independent of each other. The thickness of each layer is, for example, 10 to 100 nm.

In the case of forming the hole injection/hole transport layer as the hole injection layer 22 and the hole transport layer 23, the material of the hole injection/hole transport layer may be, for example, 4,4′-bis[N-(1-naphthyl)-N-phenylamino]biphenyl (α-NPD). The thickness of the hole injection/hole transport layer may be, for example, 30 nm.

On the hole transport layer 23, the light-emitting layers 24R, 24G, and 24B are separately formed (by patterning) to correspond to the sub-pixels 2R, 2G, and 2B, and cover the openings 15R, 15G, and 15B of the edge cover 15, respectively (S4).

As described above, a material with a high light-emitting efficiency, such as a low-molecular fluorescent dye or a metal complex, is used for each of the light-emitting layers 24R, 24G, and 24B.

Examples of the material of the light-emitting layers 24R, 24G, and 24B include, but are not particularly limited to, anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, stilbene, and derivatives thereof; a tris(8-quinolinolato)aluminum complex; a bis(benzoquinolinolato)beryllium complex; a tri(dibenzoylmethyl)phenanthroline europium complex; and ditolylvinyl biphenyl.

The thickness of each of the light-emitting layers 24R, 24G, and 24B is 10 to 100 nm, for example.

The production method and production apparatus of the present invention can be especially suitable for formation of such light-emitting layers 24R, 24G, and 24B.

The method for patterning the light-emitting layers 24R, 24G, and 24B formed by the production method and production apparatus of the present invention is described in detail later.

By the same method as that in the hole injection layer vapor-deposition step S2, the electron transport layer 25 is vapor-deposited on the entire display region of the TFT substrate 10 to cover the hole transport layer 23 and the light-emitting layers 24R, 24G, and 24B (S5).

By the same method as that in the hole injection layer vapor-deposition step S2, the electron injection layer 26 is vapor-deposited on the entire display region of the TFT substrate 10 to cover the electron transport layer 25 (S6).

Examples of the material of the electron transport layer 25 and the electron injection layer 26 include, but are not particularly limited to, quinoline, perylene, phenanthroline, bisstyryl, pyrazine, triazole, oxazol, oxadiazole, fluorenone, and derivatives thereof and metal complexes thereof; and lithium fluoride (LiF).

Specific examples thereof include Alq3 (tris(8-hydroxyquinoline)aluminum), anthracene, naphthalene, phenanthrene, pyrene, anthracene, perylene, butadiene, coumarin, acridine, stilbene, 1,10-phenanthroline, and derivatives thereof and metal complexes thereof; and LiF.

As described above, the electron transport layer 25 and the electron injection layer 26 may be integrated or may be formed as layers independent of each other. The thickness of each layer is 1 to 100 nm, for example, preferably 10 to 100 nm. Also, the total thickness of the electron transport layer 25 and the electron injection layer 26 is 20 to 200 nm, for example.

Typically, Alq₃ is used as the material of the electron transport layer 25, and LiF is used as the material of the electron injection layer 26. For example, the thickness of the electron transport layer 25 is 30 nm, and the thickness of the electron injection layer 26 is 1 nm.

By the same method as that in the hole injection layer vapor-deposition step S2, the second electrode 27 is vapor-deposited on the entire display region of the TFT substrate 10 to cover the electron injection layer 26 (S7). As a result, the organic EL elements 20 each including the organic EL layer, the first electrode 21, and the second electrode 27 are formed on the TFT substrate 10.

For the material (electrode material) of the second electrode 27, a material such as a metal with a small work function is suitable. Examples of such an electrode material include magnesium alloys (e.g., MgAg), aluminum alloys (e.g., AlLi, AlCa, AlMg), and metal calcium. The thickness of the second electrode 27 is 50 to 100 nm, for example.

Typically, the second electrode 27 is formed from a 50-nm-thick aluminum thin film.

Subsequently, as illustrated in FIG. 1, the TFT substrate 10 with the organic EL elements 20 formed thereon and the sealing substrate 40 are attached with the adhesive layer 30, so that the organic EL elements 20 are sealed (S8).

The material of the adhesive layer 30 may be, for example, sealing resin or fritted glass. The sealing substrate 40 is, for example, an insulating substrate (e.g., glass substrate or plastic substrate) with a thickness of 0.4 to 1.1 mm. The sealing substrate 40 may also be engraved glass.

Here, the vertical length and the horizontal length of the sealing substrate 40 may be appropriately adjusted to suit the size of the subject organic EL display device 1. The organic EL elements 20 may be sealed using an insulating substrate of substantially the same size as that of the insulating substrate 11 of the TFT substrate 10, and these substrates may be cut according to the size of the subject organic EL display device 1.

Also, the method for sealing the organic EL elements 20 is not particularly limited to the above method, and may be any other sealing method. Examples of the other sealing method include a method of filling the space between the TFT substrate 10 and the sealing substrate 40 with a resin.

Also, on the second electrode 27, a protective film (not illustrated) may be provided to cover the second electrode 27 so as to prevent oxygen and moisture in the outside air from entering the organic EL elements 20.

The protective film can be formed from an insulating or conductive material. Examples of such a material include silicon nitride and silicon oxide. The thickness of the protective film is 100 to 1000 nm, for example.

These steps produce the organic EL display device 1.

In this organic EL display device 1, holes are injected from the first electrodes 21 into the organic EL layers when the TFTs 12 are turned on by signal input through the conductive lines 14. Meanwhile, electrons are injected from the second electrode 27 into the organic EL layers, and the holes and electrons recombine in each of the light-emitting layers 24R, 24G, and 24B. The energy from the recombination of the holes and electrons excites the luminescent materials, and when the excited materials go back to the ground state, light is emitted. Controlling the luminance of the light emitted from each of the sub-pixels 2R, 2G, and 2B enables display of a predetermined image.

Next, the light-emitting layer vapor-deposition step S4 in the method for producing an organic EL element according to the present embodiment, the mask for production of an organic EL element according to the present embodiment, and the apparatus for producing an organic EL element according to the present embodiment are described.

The mask for production of an organic EL element according to the present embodiment is used for the apparatus and method for producing an organic EL element according to the present embodiment which perform vapor deposition while moving the substrate relatively to the vapor-deposition unit including the mask and the vapor-deposition source in the given order from the substrate side. First, the mask for production of an organic EL element according to the present embodiment is described in detail, and the apparatus and method for producing an organic EL element according to the present embodiment (in particular, light-emitting layer vapor-deposition step S4) are described later.

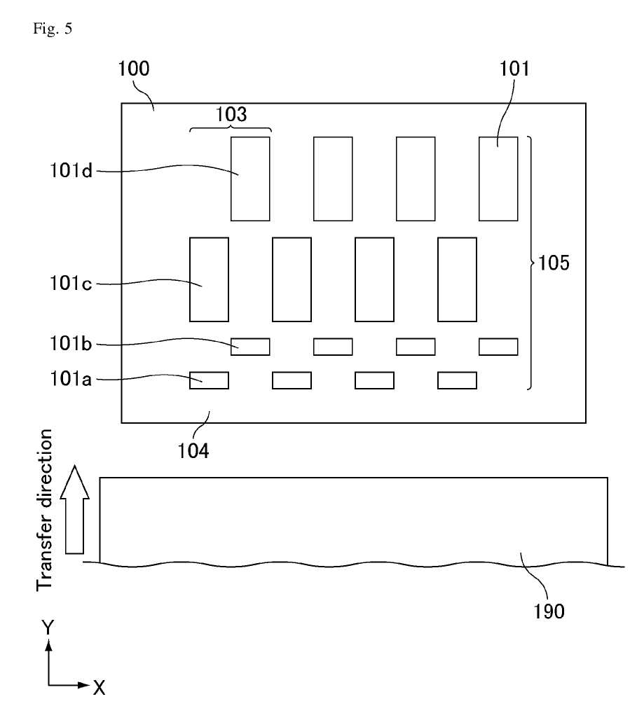

FIG. 5 is a schematic plan view of a mask for production of an organic EL element according to Embodiment 1.

As illustrated in FIG. 5, a mask 100 for production of an organic EL element according to the present embodiment is a member that has a flat-plate shape and includes a thin, flat-plate-shaped patterning portion 105 provided with an opening pattern. The patterning portion 105 includes opening regions 101 in each of which mask openings (through holes; not illustrated in FIG. 5) for patterning are formed. The opening regions 101 are arranged in a staggered pattern with four rows and eight columns. This arrangement can give a higher degree of freedom to the design of the apparatus for producing an organic EL element including the mask 100, easing the restriction in the production apparatus.

In each embodiment, the Y-axial direction and the X-axial direction are set to be parallel to the patterning portion 105.

It is important that the number of rows in the vertical direction (Y-axial direction) for the opening regions 101 is four. Meanwhile, the number of columns in the horizontal direction (X-axial direction) for the opening regions 101 may be any number not smaller than two, and can appropriately be increased or decreased in accordance with the length in the X-axial direction of the vapor-deposition target region of the substrate.

The opening regions 101 include first opening regions 101a, second opening regions 101b, third opening regions 101c, and fourth opening regions 101d arranged in a staggered pattern. The opening regions 101a, 101b, 101c, and 101d are arranged alternately in the given order in the Y-axial direction. The opening regions 101a and 101c are arranged at the same position in the X-axial direction, and the opening regions 101b and 101d are arranged at the same position in the X-axial direction. The opening regions 101a, 101b, 101c, and 101d are at different positions from each other in the Y-axial direction, and thus the opening regions 101a, 101b, 101c, and 101d do not overlap each other in the Y-axial direction. The opening regions 101a are at the outermost positions in the Y-axial direction. Any other mask openings for patterning are not formed on the side of the opening regions 101a opposite to the opening regions 101c, i.e., between the opening regions 101a and an edge 104 of the mask 100 adjacent to the opening regions 101a in the Y-axial direction. Also, any other mask openings for patterning are not formed on the side of the opening regions 101b opposite to the opening regions 101d, i.e., between the opening regions 101b and the edge 104.

The mask 100 (patterning portion 105) is provided with opening blocks 103 including the first to fourth opening regions 101a to 101d. The opening blocks 103 are arranged at an equal pitch in the X-axial direction, and have the same configuration, i.e., the same opening pattern.

The apparatus for producing an organic EL element including the mask 100 (the later-described apparatus for producing an organic EL element according to the present embodiment) and the light-emitting layer vapor-deposition step S4 utilizing the mask 100 (method for producing an organic EL element according to the present embodiment) both perform vapor deposition of a luminescent material on a substrate 190 while transferring (moving) the substrate 190 relatively to the mask 100 in the Y-axial direction at a constant speed such that the substrate 190 face the first, second, third, and fourth opening regions 101a, 101b, 101c, and 101d in the given order. This means that vapor-deposition particles (evaporated material) are vapor-deposited on the substrate 190 via the mask openings in the first opening regions 101a first; vapor-deposition particles are vapor-deposited on the substrate 190 via the mask openings in the second opening regions 101b; vapor-deposition particles are vapor-deposited on the substrate 190 via the mask openings in the third opening regions 101c; and then vapor-deposition particles are vapor-deposited on the substrate 190 via the mask openings in the fourth opening regions 101d.

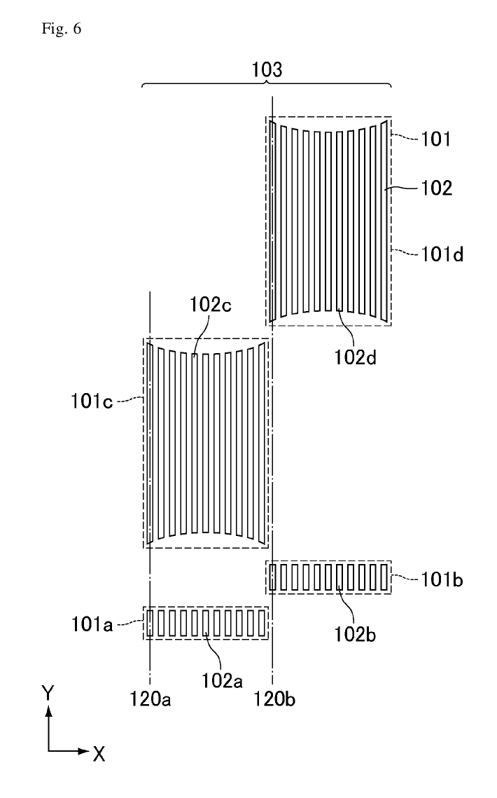

FIG. 6 is a schematic plan view of the mask for production of an organic EL element according to Embodiment 1, illustrating one opening block in an enlarged view.

As illustrated in FIG. 6, each opening region 101 is provided with mask openings (through holes) 102. The first, second, third, and fourth opening regions 101a, 101b, 101c, and 101d are respectively provided with first, second, third, and fourth mask openings 102a, 102b, 102c, and 102d arranged in the X-axial direction. The mask openings 102a, 102b, 102c, and 102d each have an elongated shape in a plan view (as viewed from the Z-axial direction), and are arranged in the Y-axial direction.

The third mask openings 102c are in one-to-one correspondence with the first mask openings 102a. Each mask opening 102c is arranged at the same position as the corresponding mask opening 102a in the X-axial direction, and each mask opening 102c and the corresponding mask opening 102a are arranged on the same straight line 120a that is parallel to the Y-axial direction. Thereby, when the substrate (not illustrated in FIG. 6) is moved relatively to the mask 100 in the Y-axial direction, on the regions (sub-pixels) on which the vapor-deposition material has been vapor-deposited via the mask openings 102a, the vapor-deposition material is vapor-deposited again via the mask openings 102c.

Similarly, the fourth mask openings 102d are in one-to-one correspondence with the second mask openings 102b. Each mask opening 102d is arranged at the same position as the corresponding mask opening 102b in the X-axial direction, and each mask opening 102d and the corresponding mask opening 102b are arranged on the same straight line 120b that is parallel to the Y-axial direction. Thereby, when the substrate is moved relatively to the mask 100 in the Y-axial direction, on the regions (sub-pixels) on which the vapor-deposition material has been vapor-deposited via the mask openings 102b, the vapor-deposition material is vapor-deposited again via the mask openings 102d.

Also, mask opening groups formed by all the first mask openings 102a and all the second mask openings 102b are arranged at an equal pitch in the X-axial direction. The pitch is made the same as the pixel pitch in the X-axial direction. Similarly, mask opening groups formed by all the third mask openings 102c and all the fourth mask openings 102d are arranged at an equal pitch in the X-axial direction. The pitch is made the same as the pixel pitch in the X-axial direction. This configuration allows formation of the stripe-patterned light-emitting layers 24R, 24G or 24B on the entire vapor-deposition target region of the substrate just by one-time transfer of the substrate relatively to the mask 100 in the Y-axial direction.

The major feature of the present embodiment is that the length in the Y-axial direction of each of the upstream-side mask openings which face the substrate first, i.e., the first and second mask openings 102a and 102b, is the shortest of all the lengths of the mask openings 102, and is shorter than the length in the Y-axial direction of each of the third and fourth mask openings 102c and 102d.

Without the first and second mask openings 102a and 102b, the region on which vapor deposition is to be performed via the fourth mask openings 102d is exposed to contaminants present in the vapor-deposition chamber while vapor deposition is performed via the third mask openings 102c. As the time for vapor deposition via the third mask openings 102c becomes longer, a contaminant layer formed on the hole transport layer 23 in the region on which vapor deposition is to be performed via the fourth mask openings 102d becomes thicker, which more significantly decreases the luminance.

The experimental results obtained by the inventors show that stitching unevenness can be reduced by decreasing the amount of contaminants directly sticking to the hole transport layer and providing an ultrathin light-emitting layer on the contaminant layer.

This is the reason that the present embodiment sets the length of each of the upstream-side first and second mask openings 102a and 102b to be short as described above. This configuration enables vapor deposition via the second mask openings 102b for a short period of time immediately after the start of vapor deposition via the first mask openings 102a. The configuration can therefore give the minimum thickness to the contaminant layer formed directly on the hole transport layer 23 and can form an ultrathin light-emitting layer on the ultrathin contaminant layer, not only in the region on which vapor deposition is performed via the first and third mask openings 102a and 102c but also in the region on which vapor deposition is performed via the second and fourth mask openings 102b and 102d. This configuration can therefore prevent a decrease in the luminance in the region on which vapor deposition is performed via the second and fourth mask openings 102b and 102d.

The first factor preventing a decrease in the luminance is the small amount of contaminants sticking directly to the hole transport layer 23, i.e., the small amount of resistance components, which prevent a decrease in injection efficiency of holes into the light-emitting layer. The second factor is the presence of the ultrathin light-emitting layer, which promotes hopping transport of holes.

Here, the second factor is described in detail.

In the region on which vapor deposition is to be performed via the fourth mask openings 102d, since the patterned light-emitting layer is not formed until vapor deposition via the third mask openings 102c is finished, the amount of contaminants sticking to the region is considered to be large. That is, in the region on which vapor deposition is performed via the first and third mask openings 102a and 102c, an ultrathin first contaminant layer, an ultrathin light-emitting layer, a second contaminant layer, and a common light-emitting layer having the desired thickness (i.e., light-emitting layer 24R, 24G, or 24B) are stacked in the given order on the hole transport layer 23. In the region on which vapor deposition is performed via the second and fourth mask openings 102b and 102d, an ultrathin third contaminant layer, an ultrathin light-emitting layer, a fourth contaminant layer, and a common light-emitting layer having the desired thickness (i.e., light-emitting layer 24R, 24G or 24B) are stacked in the given order on the hole transport layer 23. The fourth contaminant layer is considered to have a greater thickness than the second contaminant layer.

However, since the third contaminant layer is very thin, holes injected from the hole transport layer 23 into the third contaminant layer can be injected into the ultrathin light-emitting layer with hardly any decrease in the injection efficiency. The holes are then transported through the ultrathin light-emitting layer and the fourth contaminant layer by hopping transport, and injected into the common light-emitting layer having the desired thickness where the holes recombine with electrons to form excitons, thereby causing emission of light. In other words, the ultrathin light-emitting layer at the same energy level as the common light-emitting layer allows smoother hole hopping transport, leading to more efficient injection of holes into the common light-emitting layer having the desired thickness. This configuration can prevent a decrease in the luminance in the region on which vapor deposition is performed via the second and fourth mask openings 102b and 102d, and can reduce the difference in luminance between the above region and the region on which vapor deposition is performed via the first and third mask openings 102a and 102c. That is, this configuration can prevent stitching unevenness.

Also in the region on which vapor deposition is performed via the first and third mask openings 102a and 102c, since the first contaminant layer is very thin, holes injected from the hole transport layer 23 into the first contaminant layer are injected into the ultrathin light-emitting layer without any decrease in the injection efficiency. The holes are then transported through the ultrathin light-emitting layer and the second contaminant layer by hopping transport, and injected into the common light-emitting layer having the desired thickness where the holes recombine with electrons to form excitons, thereby causing emission of light.

The stitching unevenness can be effectively prevented by decreasing the amount of contaminants sticking directly to the hole transport layer 23 as described above. Alternatively, the stitching unevenness can be prevented by the same principle by forming a hole injection layer or an electron-blocking layer in place of the hole transport layer 23 as a layer adjacent to the light-emitting layer 24R, 24G or 24B. Hereinafter, the hole injection layer, the hole transport layer, or the electron-blocking layer is also referred to collectively as a hole injection/transport layer.

Each ultrathin light-emitting layer may have any thickness with which hole hopping transport occurs. The thickness is preferably not higher than 10%, more preferably not higher than 5%, of the thickness of the common light-emitting layer. Too thick an ultrathin light-emitting layer may produce a thick third contaminant layer on the hole injection/transport layer in the region on which vapor deposition is performed via the second and fourth mask openings 102b and 102d, leading to a large decrease in the luminance in this region. In contrast, too thin an ultrathin light-emitting layer may be in an island shape which fails to allow efficient hole hopping transport. The thickness of each ultrathin light-emitting layer is therefore preferably not smaller than 1 nm (10 Å).

Each of the first and second mask openings 102a and 102b may have any length in the Y-axial direction that allows hole hopping transport through the ultrathin light-emitting layers formed via those openings. Still, the lengths are preferably set such that each ultrathin light-emitting layer has the favorable thickness described above. The length of each mask opening 102a is preferably not higher than 10%, more preferably not higher than 5%, of the length of the third mask opening 102c corresponding to the mask opening 102a. Also, the length of each mask opening 102a is preferably set such that the thickness of the ultrathin light-emitting layer formed via the mask opening 102a is not smaller than 1 nm. Similarly, the length of each mask opening 102b is more preferably not higher than 10%, more preferably not higher than 5%, of the length of the fourth mask opening 102d corresponding to the mask opening 102b. Also, the length of each mask opening 102b is preferably set such that the thickness of the ultrathin light-emitting layer formed via the mask opening 102b is not smaller than 1 nm. The appropriate lower limit for each of the mask openings 102a and 102b can be easily calculated from the thickness of the ultrathin light-emitting layer, the moving rate of the substrate relative to the mask 100, and the film formation rate on the substrate surface.

The shape of each of the first and second mask openings 102a and 102b as viewed from the Z-axial direction may be any shape. The mask openings 102a and 102b may each be a slit opening elongated in the Y-axial direction as illustrated in FIG. 6. Each of the mask openings 102a and 102b may be divided into portions (mask opening portions), and the mask opening portions may be arranged in the Y-axial direction. In other words, each of the mask openings 102a and 102b may be a mask opening line including mask opening portions arranged in the Y-axial direction. In this case, the length in the Y-axial direction of each of the first and second mask openings 102a and 102b means the total length in the Y-axial direction of all the mask opening portions included in the mask opening 102a or 102b.

The length in the Y-axial direction of each of the third and fourth mask openings 102c and 102d may be any length, and can appropriately be set in accordance with the thickness (e.g., 10 to 100 nm) of the common light-emitting layer (i.e., light-emitting layer 24R, 24G, or 24B) formed via the openings. The length of each of the mask openings 102c and 102d can be easily calculated from the thickness of the common light-emitting layer, the moving rate of the substrate relative to the mask, and the film formation rate on the substrate surface.

The shape of each of the third and fourth mask openings 102c and 102d as viewed from the Z-axial direction may be any shape. The mask openings 102c and 102d may each be a slit opening elongated in the Y-axial direction as illustrated in FIG. 6. Each of the mask openings 102c and 102d may be divided into portions (mask opening portions), and the mask opening portions may be arranged in the Y-axial direction. In other words, each of the mask openings 102c and 102d may be a mask opening line including mask opening portions arranged in the Y-axial direction. In this case, the length in the Y-axial direction of each of the third and fourth mask openings 102c and 102d means the total length in the Y-axial direction of all the mask opening portions included in the mask opening 102c or 102d.

The length (width) in the X-axial direction of each of the third and fourth mask openings 102c and 102d may be any length, and can appropriately be set in accordance with the length (width) in the X-axial direction of the common light-emitting layer (i.e., light-emitting layer 24R, 24G, or 24B) formed via the openings. The widths of the light-emitting layers 24R, 24G, and 24B are usually set to be greater than the respective widths of the light-emitting regions of the sub-pixels 2R, 2G, and 2B.

The length (width) in the X-axial direction of each of the first and second mask openings 102a and 102b may be any length, and can appropriately be set in accordance with the length (width) in the X-axial direction of the ultrathin light-emitting layer formed via the openings. The width of each of the mask openings 102a and 102b is preferably made substantially the same as the width of the corresponding mask opening 102c or 102d. A difference in width between each of the mask openings 102a and 102b and the corresponding mask opening 102c or 102d may cause a difference in shape between the ultrathin light-emitting layer and the common light-emitting layer, leading to poor light emission.

The same number of the second mask openings 102b is usually formed in substantially the same pattern as in the case of the first mask openings 102a, but a different number of the second mask openings 102b may be formed in a different pattern. Similarly, the same number of the fourth mask openings 102d is usually formed in substantially the same pattern as in the case of the third mask openings 102c, but a different number of the fourth mask openings 102d may be formed in a different pattern. Meanwhile, the number of the second mask openings 102b is the same as that of the fourth mask openings 102d, and the number of the first mask openings 102a is the same as that of the third mask openings 102c.

The number of the mask openings 102a, 102b, 102c, or 102d included in one of the opening regions 101a, 101b, 101c and 101d may be any number, and can appropriately be determined in accordance with the conditions such as the pitch of the nozzles of the vapor-deposition source described later, the range of vapor-deposition particles limited by the limiting plate described later, and the fineness of pixels.

The vapor-deposition particles (evaporated material) included in a vapor-deposition stream ejected from a nozzle of the vapor-deposition source described later are distributed in a certain pattern. The distribution pattern is that the amount of vapor-deposition particles is greater at positions closer to the front of the nozzles, and the amount of vapor-deposition particles is smaller at positions farther from the front of the nozzles. Hence, in the case that the lengths of all the third mask openings 102c are the same and nozzles are arranged such that each nozzle faces the center in the X-axial direction of one third opening region 101c, the portions of the resulting film formed via the mask openings 102c at positions closer to the end of the region have a smaller thickness, producing non-uniform light emission. Each mask opening 102c at the center in the X-axial direction of the corresponding mask openings 102c is therefore made to have the shortest length in the Y-axial direction, and the mask openings 102c at positions farther in the X-axial direction from those at the center are made to have a greater length in the Y-axial direction. This configuration can cancel the distribution pattern of the vapor-deposition particles when the nozzles are arranged to face the centers in the X-axial direction of the respective opening regions 101c, thereby reducing the thickness unevenness of the portions of the film formed via the mask openings 102c and thus leading to uniform light emission.

From the same viewpoint, each fourth mask opening 102d at the center in the X-axial direction of the corresponding mask openings 102d have the shortest length in the Y-axial direction, and the mask openings 102d at positions farther in the X-axial direction from the mask openings at the center are made to have a greater length in the Y-axial direction.

Since the first and second mask openings 102a and 102b are provided to form ultrathin light-emitting layers, the lengths in the Y-axial direction of the mask openings 102a can be set independently of each other, and the lengths in the Y-axial direction of the mask openings 102b can be set independently of each other. Still, the lengths in the Y-axial direction of all the mask openings 102a and 102b are preferably substantially the same. The mask 100 is usually bonded (for example, by spot welding) under tension to the mask frame, a reinforcing member. Here, in the case the lengths in the Y-axial direction of all the mask openings 102a and 102b are the same, the tension applied to the mask 100 is uniform compared with the case the lengths are not the same. Thereby, the position accuracy and pitch accuracy of the mask openings 102 can be further increased.

Examples of the material of the mask 100 include, but are not particularly limited to, metal materials such as invar material (alloy produced by adding about 36% by mass nickel to iron; this alloy may further contain a slight amount of cobalt); resin materials such as polyimide; hybrid materials containing a resin material (e.g., polyimide) and a metal material (e.g., invar material); and glass materials. The thickness of the mask 100 is not particularly limited, and may be about several tens of micrometers, for example.

As described above, the mask 100 for production of an organic EL element according to the present embodiment includes the patterning portion 105 including mask openings 102 for patterning. The patterning portion 105 includes the first to fourth opening regions 101a to 101d arranged in a staggered pattern. The first, second, third, and fourth opening regions 101a, 101b, 101c, and 101d are arranged in the given order in the Y-axial direction (first direction) parallel to the patterning portion 105. The first opening region 101a, the second opening region 101b, the third opening region 101c, and the fourth opening region 101d respectively include the first mask openings 102a, the second mask openings 102b, the third mask openings 102c, and the fourth mask openings 102d in the X-axial direction (second direction) that is parallel to the patterning portion 105 and perpendicular to the Y-axial direction. The third mask openings 102c are arranged correspondingly to the first mask openings 102a. Each of the first mask openings 102a and the third mask opening 102c corresponding to the first mask opening 102a are on the same straight line 120a that is parallel to the Y-axial direction. The fourth mask openings 102d are arranged correspondingly to the second mask openings 102b. Each of the second mask openings 102b and the fourth mask opening 102d corresponding to the second mask opening 102b are on the same straight line 120b that is parallel to the Y-axial direction. Any mask openings are not formed on the side of the first opening regions 101a opposite to the third opening regions 101c. The first mask openings 102a and the second mask openings 102b each have a shorter length in the Y-axial direction than each of the third mask openings 102c and the fourth mask openings 102d.

As described above, the mask 100 for production of an organic EL element according to the present embodiment includes the patterning portion 105 including mask openings 102 for patterning. The patterning portion 105 includes the first to fourth opening regions 101a to 101d arranged in a staggered pattern. The first, second, third, and fourth opening regions 101a, 101b, 101c, and 101d are arranged in the given order in the Y-axial direction that is parallel to the patterning portion 105. The first opening region 101a, the second opening region 101b, the third opening region 101c, and the fourth opening region 101d respectively include the first mask openings 102a, the second mask openings 102b, the third mask openings 102c, and the fourth mask openings 102d in the X-axial direction that is parallel to the patterning portion 105 and perpendicular to the Y-axial direction. Hence, this configuration can give eased restrictions in the apparatus for producing an organic EL element including the mask 100, and can pattern the entire vapor-deposition target region on the substrate 190 by one-time transfer of the substrate 190.

Also, the third mask openings 102c are arranged correspondingly to the first mask openings 102a. Each of the first mask openings 102a and the third mask opening 102c corresponding to the first mask opening 102a are on the same straight line 120a that is parallel to the Y-axial direction. The fourth mask openings 102d are arranged correspondingly to the second mask openings 102b. Each of the second mask openings 102b and the fourth mask opening 102d corresponding to the second mask opening 102b are on the same straight line 120b that is parallel to the Y-axial direction. Hence, when the substrate 190 is moved relatively to the vapor-deposition unit including the mask 100 in the Y-axial direction such that the first, second, third, and fourth opening regions 101a, 101b, 101c, and 101d face the substrate 190 in the given order, vapor-deposition particles can be vapor-deposited via the first mask openings 102a on the region corresponding to the first mask openings 102a, vapor-deposited via the second mask openings 102b on a region different from the region on which vapor deposition has been performed via the first mask openings 102a, vapor-deposited via the third mask openings 102c on the same region as the region on which vapor deposition has been performed via the first mask openings 102a, and then vapor-deposited via the fourth mask openings 102d on the same region as the region on which vapor deposition has been performed via the second mask openings 102b.

While vapor deposition via the mask openings 102 is not performed, the substrate 190 is exposed to contaminants. This produces a contaminant layer on the entire exposed surface of the substrate 190.

Also, any mask openings are not formed on the side of the first opening region 101a opposite to the third opening region 101c. The first mask openings 102a and the second mask openings 102b each have a shorter length in the Y-axial direction than each of the third mask openings 102c and the fourth mask openings 102d. Hence, vapor deposition via the first mask openings 102a can be performed first, and the vapor-deposition times via the respective first and second mask openings 102a and 102b can be shortened. Accordingly, the time during which the hole injection/transport layer is exposed to contaminants before vapor deposition via the first mask openings 102a can be minimized, and vapor deposition via the second mask openings 102b can be started slightly after the start of vapor deposition via the first mask openings 102a. As a result, in the region on which vapor deposition is performed via the first mask openings 102a, a very thin contaminant layer and a very thin light-emitting layer can be formed in the given order on the hole injection/transport layer, and similarly, in the region on which vapor deposition is performed via the second mask openings 102b, a very thin contaminant layer and a very thin light-emitting layer can be formed in the given order on the hole injection/transport layer.

After the vapor deposition via the first mask openings 102a, a common light-emitting layer having the desired thickness can be formed by vapor deposition via the third mask openings 102c on the very thin light-emitting layer formed via the first mask openings 102a, with a contaminant layer in between. After the vapor deposition via the second mask openings 102b, a common light-emitting layer having the desired thickness can be formed by vapor deposition via the fourth mask openings 102d on the very thin light-emitting layer formed via the second mask openings 102b, with a contaminant layer in between.

As a result, in the region on which vapor deposition is performed via the first and third mask openings 102a and 102c (hereinafter, this region is also referred to as a front-line region), a very thin first contaminant layer, a very thin light-emitting layer, a second contaminant layer, and a common light-emitting layer having the desired thickness can be formed in the given order on the hole injection/transport layer. In the region on which vapor deposition is performed via the second and fourth mask openings 102b and 102d (hereinafter, this region is also referred to as a back-line region), a very thin third contaminant layer, a very thin light-emitting layer, a fourth contaminant layer, and a common light-emitting layer having the desired thickness can be formed in the given order on the hole injection/transport layer.

Here, vapor deposition via the fourth mask openings 102d is usually not started until vapor deposition via the third mask openings 102c is finished, and vapor deposition via the third mask openings 102c needs to be performed for a period of time that is enough for formation of the common light-emitting layer having the desired thickness. The fourth contaminant layer is thus usually thicker than the second contaminant layer. Still, in the back-line region, since the third contaminant layer is very thin, holes injected from the hole injection/transport layer into the third contaminant layer can be injected into the very thin light-emitting layer with hardly any decrease in the injection efficiency. The holes are then transported through the very thin light-emitting layer and the fourth contaminant layer by hopping transport, and injected into the common light-emitting layer having the desired thickness where the holes recombine with electrons to form excitons, thereby causing emission of light. In other words, the very thin light-emitting layer at the same energy level as the common light-emitting layer allows smoother hole hopping transport, leading to more efficient injection of holes into the common light-emitting layer having the desired thickness. This configuration can prevent a decrease in the luminance in the back-line region, and can reduce the difference in luminance between the back-line region and the front-line region. That is, this configuration can prevent luminance unevenness, particularly stitching unevenness.

Similarly, in the front-line region, since the first contaminant layer is very thin, holes injected from the hole injection/transport layer into the first contaminant layer are injected into the very thin light-emitting layer without any decrease in the injection efficiency. The holes are then transported through the very thin light-emitting layer and the second contaminant layer by hopping transport, and injected into the common light-emitting layer having the desired thickness where the holes recombine with electrons to form excitons, thereby causing emission of light.

The lengths in the Y-axial direction of the first mask openings 102a and those of the second mask openings 102b are substantially the same. Therefore, when the mask 100 is bonded (for example, by spot welding) under tension to the mask frame, a reinforcing member, the tension applied to the mask 100 is uniform, whereby the position accuracy and pitch accuracy of the mask openings 102 can be further increased.

The expression “the lengths in the Y-axial direction of the mask openings are substantially the same” as used herein means that, when the maximum length and the minimum length of the lengths in the Y-axial direction of the mask openings are respectively defined as Ymax and Ymin, a value (in percentage) calculated from the following formula (1) is not higher than 10%. In other words, the expression “the lengths in the Y-axial direction of the first mask openings 102a and the lengths in the Y-axial direction of the second mask openings 102b are substantially the same” means that, when the maximum length and the minimum length of the lengths in the Y-axial direction of the first mask openings 102a and the second mask openings 102b are respectively defined as Ymax and Ymin, a value calculated from the following formula (1) is not higher than 10%. The value calculated from the following formula (1) is preferably not higher than 5%, more preferably not higher than 2%.

$$\frac{Y max - Y min}{( Y max + Y min ) / 2} \times 100 \qquad ( 1 )$$

The formula (1) calculates the range of change in the lengths in the Y-axial direction of the mask openings by dividing the range of change in the finishing accuracy of the lengths in the Y-axial direction of the mask openings (numerator) by the average finishing accuracy (denominator). A common method for producing a mask sufficiently allows formation of mask openings with a value calculated from the formula (1) of not higher than 10%.

The apparatus and method (in particular, light-emitting layer vapor-deposition step S4) for producing an organic EL element according to the present embodiment are described in detail.

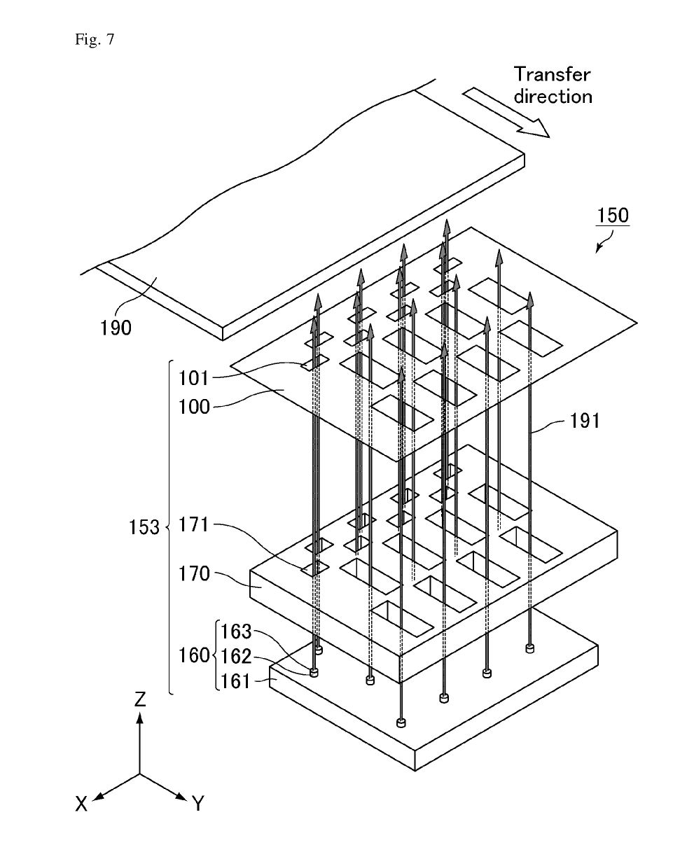

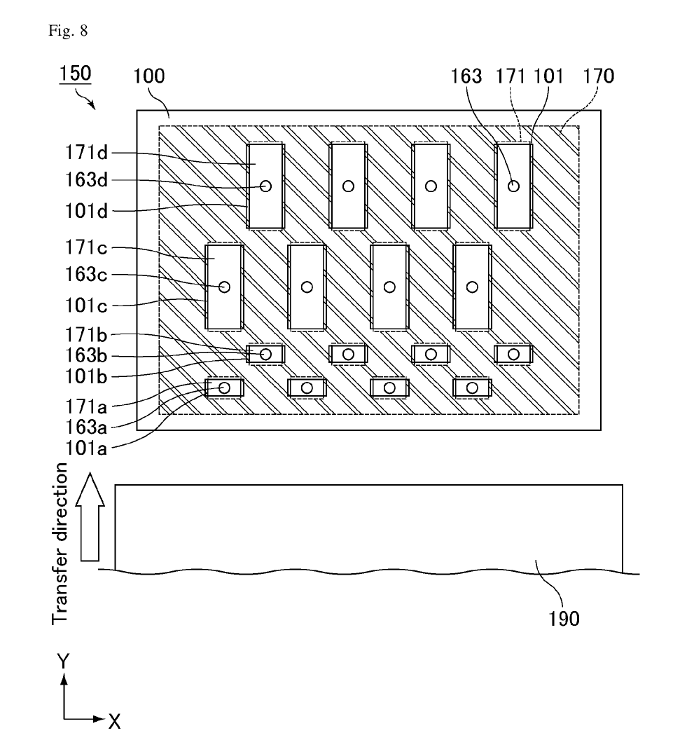

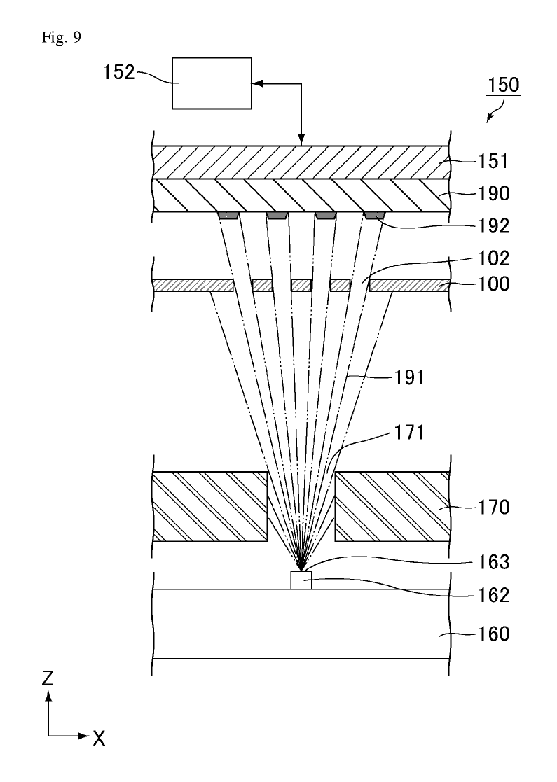

FIG. 7 is a schematic perspective view of an apparatus for producing an organic EL element according to Embodiment 1. FIG. 8 is a schematic plan view of the apparatus for producing an organic EL element according to Embodiment 1. FIG. 9 is a schematic cross-sectional view of the apparatus for producing an organic EL element according to Embodiment 1, illustrating a cross section perpendicular to the Y-axial direction.

As illustrated in FIGS. 7 to 9, an apparatus 150 for producing an organic EL element according to the present embodiment is a vacuum vapor-deposition apparatus employing scanning film-formation method, and includes a vapor-deposition chamber (vacuum chamber, not illustrated), a vacuum pump connected to the vapor-deposition chamber (not illustrated), a substrate holder 151, a transfer mechanism 152, a shutter (not illustrated), an alignment device (not illustrated), a drive control device (not illustrated) configured to control driving of the production apparatus 150, and a vapor-deposition unit 153. The vapor-deposition unit 153 includes a vapor-deposition source 160, a limiting plate 170, the mask 100 for production of an organic EL element according to Embodiment 1, a mask frame (not illustrated), and a unit holder (not illustrated). Above the mask 100 is transferred the substrate 190 on which vacuum vapor-deposition (film formation) is performed. The mask 100, the limiting plate 170, and the vapor-deposition source 160 are disposed in the given order from the substrate 190 side.

The vapor-deposition chamber is a vessel used for forming the space in which vacuum vapor deposition is performed. The vapor-deposition unit 153, the substrate holder 151, at least part of the transfer mechanism 152, and at least part of the alignment device are provided in the vapor-deposition chamber. When vapor deposition is performed, the vapor-deposition chamber is evacuated (depressurized) by the vacuum pump, and the vapor-deposition chamber is maintained in a high-vacuum state (e.g., ultimate vacuum: not higher than 10-4 Pa) at least while vapor deposition is performed.

The unit holder is configured to unite the mask 100, the limiting plate 170, and the vapor-deposition source 160 at least while vapor deposition is performed. The unit holder unites the members in order to maintain constant the relative positions and angles of the mask 100, the limiting plate 170, and nozzles 162 of the vapor-deposition source 160 during the vapor deposition.

The substrate holder 151 is configured to hold the substrate 190, and is provided in the upper portion inside the vapor-deposition chamber. The substrate holder 151 holds the substrate 190 such that the vapor-deposition target surface faces the mask 100. The substrate holder 151 is preferably an electrostatic chuck.

As described above, up to the light-emitting layer vapor-deposition step S4, the TFTs 12, the conductive lines 14, the interlayer film 13, the first electrodes 21, the edge cover 15, and the hole injection/transport layer (the hole injection layer 22, the hole transport layer 23, and/or the electron-blocking layer) are formed on the insulating substrate 11 of the substrate 190.

The substrate holder 151 is connected to the transfer mechanism 152. The transfer mechanism 152 guides the substrate holder 151 in the Y-axial direction to allow the substrate 190 to face the mask 100. The transfer mechanism 152 moves the substrate holder 151 and the substrate 190 held by the substrate holder 151 in the Y-axial direction at a constant speed to have them pass the vicinity of the mask 100. Meanwhile, the vapor-deposition unit 153 is fixed and allowed to stand still in the vapor-deposition chamber at least while vapor deposition is performed. Thereby, the transfer mechanism 152 can move the substrate 190 relatively to the vapor-deposition unit 153 in the Y-axial direction. The transfer mechanism 152 may include, for example, a straight-line guide extending in the Y-axial direction, a ball screw extending in the Y-axial direction, a ball nut screwed together with the ball screw, a drive motor (electric motor) configured to rotatively drive the ball screw (e.g., servomotor, stepping motor), and a motor drive control device electrically connected to the drive motor.

The transfer mechanism 152 may be any mechanism that can move the substrate 190 relatively to the vapor-deposition unit 153. The transfer mechanism 152 may therefore be connected to the substrate holder 151 and the vapor-deposition unit 153, and both the substrate holder 151 and the vapor-deposition unit 153 may be moved by the transfer mechanism 152. Also, the transfer mechanism 152 may be connected to the vapor-deposition unit 153, and the vapor-deposition unit 153 may be moved by the transfer mechanism 152 with the substrate 190 and the substrate holder 151 being fixed in the vapor-deposition chamber.

The mask 100 is disposed with the mask openings being arranged in the Y-axial direction such that the first, second, third, and fourth opening regions 101a, 101b, 101c, and 101d face the substrate 190 in the given order.

The mask 100 is smaller than the substrate 190, and has a shorter length in the Y-axial direction than the substrate 190. Thereby, the mask 100 can be reduced in size, and the productivity of the mask 100 can be secured even when the size of the substrate 190 is increased. Also, deflection of the mask 100 caused by its own weight can be reduced.

The mask frame is a frame-shaped reinforcing member. The mask 100 is bonded (for example, by spot welding) under tension to the mask frame. This configuration reduces deflection of the mask 100 caused by its own weight.

In order to prevent the substrate 190 from being damaged during transfer of the substrate 190, the substrate 190 is moved with a certain space over the mask 100 during vapor deposition. Here, the size of the space is not particularly limited, and may be appropriately set. For example, this gap may be about the same as the space between the mask and the substrate set in a common scanning vapor-deposition method.

The vapor-deposition source 160 is provided in the lower portion of the vapor-deposition chamber, and is configured to heat a material to be vacuum vapor-deposited (here, a light-emitting material; preferably an organic material) to vaporize the material, i.e., evaporate or sublimate the material, and eject the vaporized material into the vapor-deposition chamber. More specifically, the vapor-deposition source 160 includes an evaporating portion (not illustrated), a scattering portion 161 that is connected to the evaporating portion and forms a space in which the vaporized material is scattered, and nozzles 162 provided periodically in the upper portion (the mask 100 side portion) of the scattering portion 161. The evaporating portion includes a heat-resistant vessel (not illustrated) designed to house the material, such as a crucible, and a heating device (not illustrated) configured to heat the material housed in the vessel, such as a heater and a heating power source. The nozzles 162 each have an orifice (opening) 163 at its end, and the orifice 163 penetrates the nozzle to the scattering portion 161. When the material is placed in the vessel in the evaporating portion and vaporized by heating with the heating device, the vaporized material (vapor-deposition particles) are scattered in the scattering portion 161, and eventually ejected from the orifices 163. As a result, vapor-deposition streams 191, which are flows of vapor-deposition particles, are generated from the orifices 163, and the vapor-deposition streams 191 (vapor-deposition particles) spread isotropically from the orifices 163.

As illustrated in FIG. 8, the orifices 163 are arranged in a staggered pattern similarly to the opening regions 101, and are in one-to-one correspondence with the opening regions 101. Arranging the orifices 163 in a staggered pattern enables wide intervals between the adjacent orifices 163. This configuration enables reduction of scattering of vapor-deposition particles in the vicinities of the nozzles 162, and reduction of defects such as blurring. The orifices 163 include first, second, third, and fourth orifices 163a, 163b, 163c, and 163d respectively corresponding to the first, second, third, and fourth opening regions 101a, 101b, 101c, and 101d.

The expression “orifices corresponding to the opening regions” as used herein means orifices designed to allow vapor-deposition particles ejected therefrom to pass through the corresponding opening regions.

The specific positions of the orifices 163 are not particularly limited, and the orifices 163 may be arranged to face the center of the corresponding opening regions 101, for example. Also, as viewed from the Z-axial direction, the orifices 163 may be arranged to overlap the corresponding opening regions 101.

Arranging one orifice 163 correspondingly to one opening region 101 enables utilization of a vapor-deposition particle region with a high density of particles (a region with a large number of vapor-deposition particles) in the distributed pattern of one vapor-deposition stream 191, thereby achieving film formation in a short time.

The shape of each orifice 163 as viewed from the Z-axial direction is not particularly limited, and can appropriately be designed. Examples of the shape include a circle, an oval, a rectangle, and a square. The planar shapes of the orifices 163 as viewed from the Z-axial direction can be designed independently of each other. Still, usually, the planar shapes of the orifices 163 as viewed from the Z-axial direction are all designed to be the same planar shape. The size (area) of each orifice 163 is not particularly limited either, and can appropriately be designed. The sizes (areas) of the orifices 163 can be designed independently of each other. Still, usually, the sizes of the orifices 163 are all designed to be the same size.

The kind of the vapor-deposition source 160 is not particularly limited, and may be, for example, a point vapor-deposition source (point source), a line vapor-deposition source (line source), or a surface vapor-deposition source. The heating method employed by the vapor-deposition source 160 is not particularly limited, and may be, for example, resistive heating, an electron beam method, laser evaporation, high frequency induction heating, or an arc method.

The space between the mask 100 and the surface on which the orifices 163 are formed is also maintained to the predetermined size while vapor deposition is performed. This space is not particularly limited and can appropriately be set. For example, the space may be made about the same as the space between the mask and the surface on which orifices are formed in a common scanning vapor-deposition method.

The shutter is disposed in an insertable manner between the vapor deposition source 160 and the limiting plates 170. When the shutter is inserted therebetween, the vapor deposition streams 191 are blocked. As mentioned here, appropriate insertion of the shutter between the vapor deposition source 160 and the limiting plate 170 enables prevention of vapor deposition on an unnecessary portion (non-vapor-deposition region) of the substrate 190.

The limiting plate 170 is a thick-plate member provide with openings (through holes) 171, and is disposed to be substantially parallel to the XY plane (plane parallel to the X-axis and Y-axis) with a distance from the vapor-deposition source 160. As illustrated in FIG. 8, the openings 171 are arranged in a staggered pattern similarly to the opening regions 101, and are in one-to-one correspondence with the opening regions 101. As viewed from the Z-axial direction, the openings 171 are at substantially the same positions as those of the corresponding opening regions 101. The openings 171 include first, second, third, and fourth openings 171a, 171b, 171c, and 171d corresponding to the first, second, third, and fourth opening regions 101a, 101b, 101c, and 101d.

The space between the vapor-deposition source 160 and the limiting plate 170 is not particularly limited, and can appropriately be set. For example, the space may be made about the same as the space between the vapor-deposition source and the limiting plate set in a common scanning vapor-deposition method.

All the openings 171 are formed to have substantially the same size and substantially the same shape. The shape of each opening 171 as viewed from the Z-axial direction is, for example, a rectangle or a square. The shape of each opening 171 as viewed from the Z-axial direction is not particularly limited, and can appropriately be designed independently of each other. Still, usually, the openings 171 each are designed to have a shape including a pair of sides parallel to the Y-axial direction.

One orifice 163 is arranged below one opening 171, in a one-to-one correspondence with the opening 171. Also as viewed from the Z-axial direction, the position of each orifice 163 is substantially the same as the position of the center of the corresponding opening 171. As viewed from the Y-axial direction, each orifice 163 is at a position substantially directly below the center portion of the corresponding opening 171.

Here, the correspondence between the openings 171 and the orifices 163 is not particularly limited. For example, multiple openings 171 may be arranged correspondingly to one orifice 163, or one opening 171 may be arranged correspondingly to multiple orifices 163. The former case is described in detail in Embodiment 3. As viewed from the Y-axial direction, each orifice 163 may be arranged at a position off from the position directly below the center of the corresponding opening 171.

The expression “openings corresponding to the orifices” as used herein means openings designed to allow vapor-deposition particles ejected from the orifices to pass therethrough.

To each opening 171 rises a vapor-deposition stream 191 ejected from the corresponding orifice 163 to spread to a certain degree. Some of the vapor-deposition particles contained in the vapor-deposition stream 191 can pass through the opening 171. The other vapor-deposition particles collide and adhere to the bottom surface of the limiting plate 170 or the wall of the limiting plate 170 in the opening 171, and cannot pass through the opening 171, failing to reach the mask 100. In this manner, the limiting plate 170 prevents each vapor-deposition stream 191 from passing through the openings 171 other than the corresponding opening 171 (e.g., the opening 171 adjacent to the corresponding opening 171).

The limiting plate 170 limits the flying range of the vapor-deposition particles having been isotropically spreading immediately after ejected from the orifices 163, so as to block poorly directed components, particularly vapor-deposition particles with a relatively high velocity component in the X-axial direction, and allow favorably directed components, particularly vapor-deposition components with a relatively low velocity component in the X-axial direction, to pass therethrough. The limiting plate 170 also prevents the vapor-deposition streams 191 from reaching the substrate 190 with an unnecessarily large incident angle as viewed from the Y-axial direction, and thereby increases the directivity in the X-axial direction of the vapor-deposition particles incident on the substrate 190. Arrangement of such a limiting plate 170 enables reduction of the degree of blurring in film-formation patterning.

As illustrated in FIG. 9, since the mask 100 includes the mask openings 102 for patterning, some of the vapor-deposition particles having reached the mask 100 can pass through the mask openings 102, and can accumulate on the substrate 190 in a pattern corresponding to the mask openings 102.

Hereinbelow, the light-emitting layer vapor-deposition step S4 and the behavior of the apparatus 150 for producing an organic EL element in the light-emitting layer vapor-deposition step S4 are described.

In the light-emitting layer vapor-deposition step S4, first, the vapor-deposition chamber is depressurized into a high vacuum state. Also, the material is heated such that the vapor-deposition streams 191 are generated. Then, the substrate 190 is carried into the vapor-deposition chamber through the carry-in port (not illustrated), and is held by the substrate holder 151. At a waiting position outside the vapor-deposition range, the substrate 190 and the mask 100 are aligned by the alignment device. With the substrate 190 placed outside the vapor-deposition range, the shutter is withdrawn from between the vapor-deposition source 160 and the limiting plate 170, until the film-formation rate becomes stable. During this waiting time, a dummy substrate is placed in the vapor-deposition range, so that the dummy substrate is subjected to vapor deposition (dummy vapor deposition). After the film-formation rate becomes stable, the dummy substrate is removed.

As illustrated in FIG. 7, the substrate 190 is then moved by the transfer mechanism 152 relatively to the vapor-deposition unit 153 in the Y-axial direction at a constant speed, such that the substrate 190 and the mask 100 pass each other. As a result, as illustrated in FIG. 9, vapor-deposition particles having passed through the mask openings 102 sequentially adhere to the vapor-deposition target region of the substrate 190 that is moved relatively to the vapor-deposition unit 153, so that a stripe-patterned film (vapor-deposition film) 192 is formed. When the vapor-deposition target region of the substrate 190 has passed above the mask 100, the shutter is inserted between the vapor-deposition source 160 and the limiting plate 170. The vapor deposition on the substrate 190 is thus finished.

In the light-emitting layer vapor-deposition step S4, the above series of vapor deposition processes are performed three times with the respective three kinds of light-emitting materials by the in-line method, so that the light-emitting layers 24R, 24G and 24B having the respective three colors are formed. That is, the apparatus 150 for producing an organic EL element has three same configurations each including members such as the above vapor-deposition unit 153, and these configurations are arranged in the Y-axial direction. The order of forming the light-emitting layers 24R, 24G, and 24B is not particularly limited, and may appropriately be determined.

After all the light-emitting layers are formed by vapor deposition, the substrate 190 is transferred by the transfer mechanism 152 to the front of the carry-out port (not illustrated), and is transferred out of the vapor-deposition chamber through the carry-out port. Thereby, the light-emitting layer vapor-deposition step S4 is completed.

The light-emitting layer vapor-deposition step S4 may be performed by the multi-chamber method, not by the in-line method.

As described above, the apparatus 150 for producing an organic EL element according to the present embodiment is an apparatus for producing an organic EL element through formation of a film on the substrate 190, including the vapor-deposition unit 153 including the mask 100 for production of an organic EL element according to the present embodiment and the vapor-deposition source 160 configured to eject vapor-deposition particles; and the transfer mechanism 152 configured to move the substrate 190 relatively to the vapor-deposition unit 153 in the Y-axial direction (first direction), with the substrate 190 being away from the mask 100. The mask 100 is disposed such that the first, second, third, and fourth opening regions 101a, 101b, 101c, and 101d face the substrate 190 in the given order. The apparatus can therefore give reduced luminance unevenness and eased restrictions in the apparatus 150 for producing an organic EL element as described above.

More specifically, the apparatus 150 for producing an organic EL element according to the present embodiment includes the vapor-deposition unit 153 including the mask 100 for production of an organic EL element according to the present embodiment and the vapor-deposition source 160 configured to eject vapor-deposition particles; and the transfer mechanism 152 configured to move the substrate 190 relatively to the vapor-deposition unit 153 in the Y-axial direction (first direction), with the substrate 190 being away from the mask 100. The mask 100 for production of an organic EL element according to the present embodiment includes the patterning portion 105 including mask openings 102 for patterning. The patterning portion 105 includes the first to fourth opening regions 101a to 101d arranged in a staggered pattern. The first, second, third, and fourth opening regions 101a, 101b, 101c, and 101d are arranged in the given order in the Y-axial direction (first direction) that is parallel to the patterning portion 105. The first opening region 101a, the second opening region 101b, the third opening region 101c, and the fourth opening region 101d respectively include the first mask openings 102a, the second mask openings 102b, the third mask openings 102c, and the fourth mask openings 102d in the X-axial direction (second direction) that is parallel to the patterning portion 105 and perpendicular to the Y-axial direction. Hence, this configuration can give eased restrictions in the production apparatus 150, and can pattern the entire vapor-deposition target region on the substrate 190 by one-time transfer of the substrate 190 by the transfer mechanism 152.

Also, the apparatus 150 for producing an organic EL element according to the present embodiment includes the transfer mechanism 152 configured to move the substrate 190 relatively to the vapor-deposition unit 153 in the Y-axial direction, with the substrate 190 being away from the mask 100. The mask 100 is disposed such that the first, second, third, and fourth opening regions 101a, 101b, 101c, and 101d face the substrate 190 in the given order. The third mask openings 102c are arranged correspondingly to the first mask openings 102a. Each of the first mask openings 102a and the third mask opening 102c corresponding to the first mask opening 102a are on the same straight line 120a that is parallel to the Y-axial direction. The fourth mask openings 102d are arranged correspondingly to the second mask openings 102b. Each of the second mask openings 102b and the fourth mask opening 102d corresponding to the second mask opening 102b are on the same straight line 120b that is parallel to the Y-axial direction. Hence, vapor-deposition particles can be vapor-deposited via the first mask openings 102a on the region corresponding to the first mask openings 102a, vapor-deposited via the second mask openings 102b on a region different from the region on which vapor deposition has been performed via the first mask openings 102a, vapor-deposited via the third mask openings 102c on the same region as the region on which vapor deposition has been performed via the first mask openings 102a, and then vapor-deposited via the fourth mask openings 102d on the same region as the region on which vapor deposition has been performed via the second mask openings 102b.

While vapor deposition via the mask openings 102 is not performed, the substrate 190 is exposed to contaminants. This produces a contaminant layer on the entire exposed surface of the substrate 190.

Also, any mask openings are not formed on the side of the first opening region 101a opposite to the third opening region 101c. The first mask openings 102a and the second mask openings 102b each have a shorter length in the Y-axial direction than each of the third mask openings 102c and the fourth mask openings 102d. As a result, as described above, in the region on which vapor deposition is performed via the first and third mask openings 102a and 102c (front-line region), a very thin first contaminant layer, a very thin light-emitting layer, a second contaminant layer, and a common light-emitting layer having the desired thickness can be formed in the given order on the hole injection/transport layer. In the region on which vapor deposition is performed via the second and fourth mask openings 102b and 102d (back-line region), a very thin third contaminant layer, a very thin light-emitting layer, a fourth contaminant layer thicker than the second contaminant layer, and a common light-emitting layer having the desired thickness can be formed in the given order on the hole injection/transport layer. This configuration therefore allows smoother electron hopping transport, leading to efficient injection of electrons into the common light-emitting layer having the desired thickness, in the back-line region. This configuration can prevent a decrease in the luminance in the back-line region, and can reduce the difference in luminance between the back-line region and the front-line region. That is, this configuration can prevent luminance unevenness, particularly stitching unevenness.

Also, the method for producing an organic EL element according to the present embodiment is a method for producing an organic EL element with use of the mask 100 for production of an organic EL element according to the present embodiment. The mask 100 includes the patterning portion 105 including the mask openings 102 for patterning. The patterning portion 105 includes the first to fourth opening regions 101a to 101d arranged in a staggered pattern. The first, second, third, and fourth opening regions 101a, 101b, 101c, and 101d are arranged in the given order in the Y-axial direction (first direction) that is parallel to the patterning portion 105. The first opening region 101a, the second opening region 101b, the third opening region 101c, and the fourth opening region 101d respectively include the first mask openings 102a, the second mask openings 102b, the third mask openings 102c, and the fourth mask openings 102d in the X-axial direction (second direction) that is parallel to the patterning portion 105 and perpendicular to the Y-axial direction. The third mask openings 102c are arranged correspondingly to the first mask openings 102a. Each of the first mask openings 102a and the third mask opening 102c corresponding to the first mask opening 102a are on the same straight line 120a that is parallel to the Y-axial direction. The fourth mask openings 102d are arranged correspondingly to the second mask openings 102b. Each of the second mask openings 102b and the fourth mask opening 102d corresponding to the second mask opening 102b are on the same straight line 120b that is parallel to the Y-axial direction. Any mask openings are not formed on the side of the first opening region 101a opposite to the third opening region 101c. The first mask openings 102a and the second mask openings 102b each have a shorter length in the Y-axial direction than each of the third mask openings 102c and the fourth mask openings 102d. The method for producing an organic EL element according to the present embodiment includes a light-emitting layer vapor-deposition step S4 of causing the vapor-deposition particles to adhere to the substrate 190 via the mask 100 while moving in the Y-axial direction the substrate 190 relatively to the vapor-deposition unit 153 including the mask 100 and the vapor-deposition source 160 configured to eject vapor-deposition particles, with the substrate 190 being away from the mask 100. The mask 100 in the light-emitting layer vapor-deposition step S4 is disposed such that the first, second, third, and fourth opening regions 101a, 101b, 101c, and 101d face the substrate 190 in the given order. Accordingly, similarly to the case of the apparatus 150 for producing an organic EL element according to the present embodiment, the method can give reduced luminance unevenness and eased restrictions in the apparatus 150 for producing an organic EL element.

Arranging the first, second, third, and fourth orifices 163a, 163b, 163c, and 163d respectively corresponding to the first, second, third, and fourth opening regions 101a, 101b, 101c, and 101d in the vapor-deposition source 160 enables utilization of a vapor-deposition particle region with a high density of particles (a region with a large number of vapor-deposition particles) in the distributed pattern of each vapor-deposition stream 191, thereby achieving film formation in a short time.

The apparatus 150 for producing an organic EL element according to the present embodiment further includes the limiting plate 170 disposed between the mask 100 and the vapor-deposition source 160. The limiting plate 170 includes the first, second, third, and fourth openings 171a, 171b, 171c, and 171d respectively corresponding to the first, second, third, and fourth opening regions 101a, 101b, 101c, and 101d. Similarly, in the light-emitting layer vapor-deposition step S4, the limiting plate 170 including the first, second, third, and fourth openings 171a, 171b, 171c, and 171d respectively corresponding to the first, second, third, and fourth opening regions 101a, 101b, 101c, and 101d is disposed between the mask 100 and the vapor-deposition source 160. Arrangement of such a limiting plate 170 enables reduction of the degree of blurring in film-formation patterning.

### Embodiment 2

The features unique to the present embodiment are mainly described in the present embodiment, and the same points as in Embodiment 1 are not described. Also, the members having the same or similar functions in the present embodiment and Embodiment 1 are provided with the same or similar reference numerals, and are not described in the present embodiment.

In Embodiment 1, the vapor-deposition streams having passed through the openings in the limiting plate facing the first or third opening regions and the vapor-deposition streams having passed through the openings in the limiting plate facing the second or fourth opening regions may possibly interfere with each other. That is, the vapor-deposition streams flowing toward the first or third opening regions may spread to enter the second or fourth opening regions. As a result, defects such as color mixing or blurring may occur. In order to eliminate such a concern, the present embodiment employs additional limiting plates as well as the above limiting plate. Here, the color mixing refers to a phenomenon in which the originally emitted color is mixed with another color.

The present embodiment is substantially the same as Embodiment 1 except for the use of additional limiting plates.

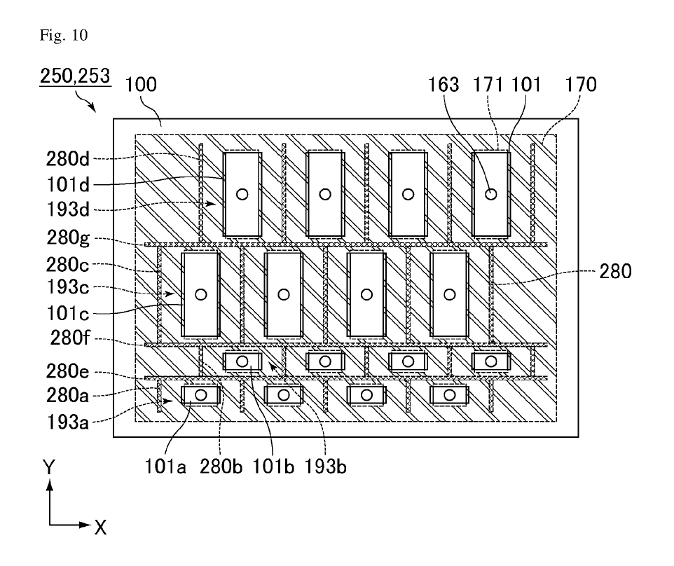

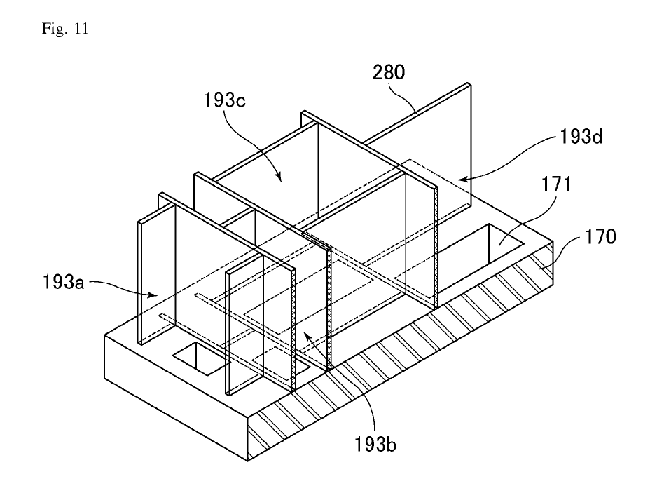

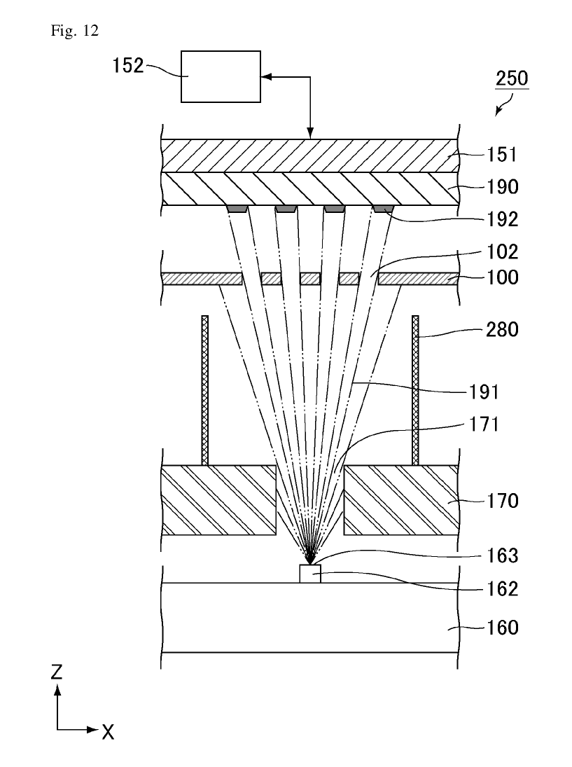

FIG. 10 is a schematic plan view of an apparatus for producing an organic EL element according to Embodiment 2. FIG. 11 is a schematic perspective view of the apparatus for producing an organic EL element according to Embodiment 2. FIG. 12 is a schematic cross-sectional view of the apparatus for producing an organic EL element according to Embodiment 2, illustrating a cross section perpendicular to the Y-axial direction.

As illustrated in FIGS. 10 to 12, a vapor-deposition unit 253 of an apparatus 250 for producing an organic EL element according to the present embodiment includes additional limiting plates 280 provided between the above mask 100 and the limiting plate 170.

The additional limiting plates 280 are plate-like members which separate the space between the mask 100 and the limiting plate 170 into four spaces 193a, 193b, 193c, and 193d respectively corresponding to the first, second, third, and fourth opening regions 101a, 101b, 101c, and 101d. With the additional limiting plates 280, vapor-deposition streams flowing toward the first opening regions 101a or the third opening regions 101c can be prevented from flowing into the second opening regions 101b or the fourth opening regions 101d even when the vapor-deposition streams spread. The present embodiment can therefore decrease the probability that defects such as color mixing and blurring occur compared with Embodiment 1.

As illustrated in FIG. 10, the additional limiting plates 280 include additional limiting plates 280a alternating with the first opening regions 101a as viewed from the Z-axial direction, additional limiting plates 280b alternating with the second opening regions 101b as viewed from the Z-axial direction, additional limiting plates 280c alternating with the third opening regions 101c as viewed from the Z-axial direction, additional limiting plates 280d alternating with the fourth opening regions 101d as viewed from the Z-axial direction, an additional limiting plate 280e arranged between the first opening regions 101a and the second opening regions 101b as viewed from the Z-axial direction, an additional limiting plate 280f arranged between the second opening regions 101b and the third opening regions 101c as viewed from the Z-axial direction, and an additional limiting plate 280g arranged between the third opening regions 101c and the fourth opening regions 101d as viewed from the Z-axial direction. The additional limiting plates 280a to 280d are disposed in the Y-axial direction, and the additional limiting plates 280e to 280g are disposed in the X-axial direction.

The additional limiting plates 280a to 280g are bonded (for example, by spot welding) to each other, and are united with the mask 100, the limiting plate 170, and the vapor-deposition source 160 by the unit holder.

The shapes of the additional limiting plates 280 are not particularly limited, and may appropriately be set independently of each other. For example, the additional limiting plates 280 may have a flat-plate shape, a bent or curved shape, or a corrugated plate shape.

The additional limiting plates 280 may each be in contact with the limiting plate 170 as illustrated in FIGS. 11 and 12, or may be spaced from the limiting plate 170.

As described above, the apparatus 250 for producing an organic EL element according to the present embodiment further includes the additional limiting plates 280 disposed between the mask 100 and the limiting plate 170. The additional limiting plates 280 separate the space between the mask 100 and the limiting plate 170 into the four spaces 193a, 193b, 193c, and 193d respectively corresponding to the first, second, third, and fourth opening regions 101a, 101b, 101c, and 101d. With the additional limiting plates 280, vapor-deposition streams flowing toward the first opening regions 101a or the third opening regions 101c can be prevented from flowing into the second opening regions 101b or the fourth opening regions 101d even when the vapor-deposition streams spread. The present embodiment can therefore decrease the probability that defects such as color mixing and blurring occur compared with Embodiment 1.

The method for producing an organic EL element according to the present embodiment employs, in the light-emitting layer vapor-deposition step S4, the additional limiting plates 280 disposed between the mask 100 and the limiting plate 170 which separate the space between the mask 100 and the limiting plate 170 into the four spaces 193a, 193b, 193c, and 193d respectively corresponding to the first, second, third, and fourth opening regions 101a, 101b, 101c, and 101d. The present embodiment can therefore decrease the probability that defects such as color mixing and blurring occur compared with Embodiment 1.

### Embodiment 3

The features unique to the present embodiment are mainly described in the present embodiment, and the same points as in Embodiments 1 and 2 are not described. Also, the members having the same or similar functions in the present embodiment and Embodiments 1 and 2 are provided with the same or similar reference numerals, and are not described in the present embodiment.

In Embodiment 1, since one orifice was provided for one opening region, nozzles are disposed densely, so that vapor-deposition particles ejected from adjacent nozzles are likely to collide with each other, which is likely to cause scattering of vapor-deposition particles. As a result, defects such as blurring may occur. In order to eliminate such a concern, arrangement of orifices is changed in the present embodiment.

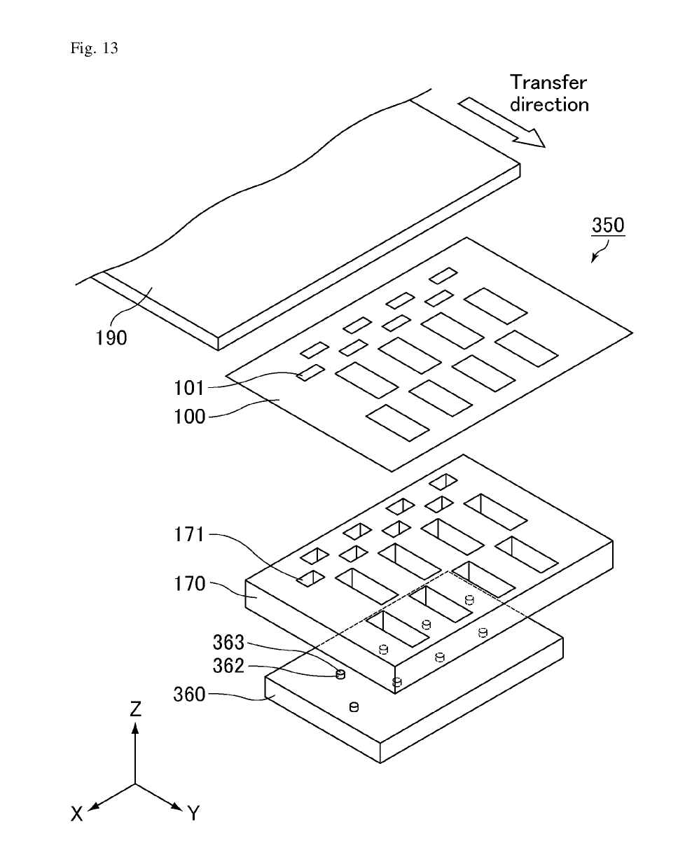

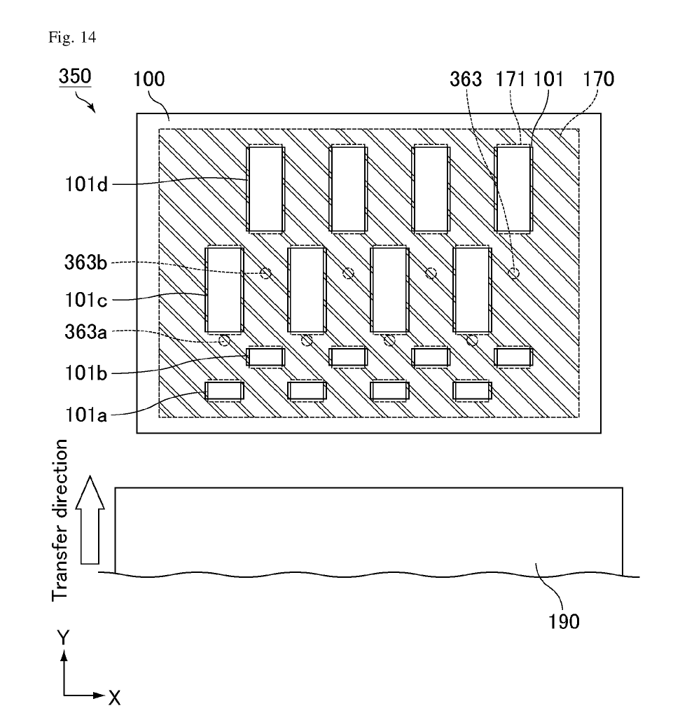

FIG. 13 is a schematic perspective view of an apparatus for producing an organic EL element according to Embodiment 3. FIG. 14 is a schematic plan view of the apparatus for producing an organic EL element according to Embodiment 3.

As illustrated in FIG. 13, an apparatus 350 for producing an organic EL element according to the present embodiment includes a vapor-deposition source 360. The vapor-deposition source 360 includes nozzles 362 each provided at an end with an orifice 363.

The present embodiment is substantially the same as Embodiment 1 except for use of the vapor-deposition source 360 in place of the vapor-deposition source of Embodiment 1. The vapor-deposition source 360 is substantially the same as the vapor-deposition source of Embodiment 1 except for the arrangement of the nozzles.

As illustrated in FIG. 14, the orifices 363 are arranged in a staggered pattern, and one orifice 363 is arranged correspondingly to two opening regions 101 adjacent to each other in the Y-axial direction. That is, the orifices 363 include first orifices 363a corresponding to the first and third opening regions 101a and 101c, and second orifices 363b corresponding to the second and fourth opening regions 101b and 101d. Such correspondence of one orifice 363 to two opening regions 101 enables decrease in the arrangement density of the nozzles 362, reducing scattering of vapor-deposition particles. The present embodiment can therefore decrease the probability that defects such as blurring occur compared with Embodiment 1.

The specific arrangement positions of the orifices 363 are not particularly limited, and can appropriately be determined. Still, as viewed from the Z-axial direction, the first orifices 363a are preferably arranged at the centers between the center portions of the first opening regions 101a and the center portions of the third opening regions 101c, and the second orifices 363b are preferably arranged at the centers between the center portions of the second opening regions 101b and the center portions of the fourth opening regions 101d. Thereby, the center portion of each of the first opening regions 101a and the center portion of the corresponding third opening region 101c are symmetrically positioned with the axis which passes through the corresponding orifice 363a as the center. Thus, by providing symmetrical distribution of vapor-deposition particles with this axis as the center, the portions of the vapor-deposition streams with substantially the same density of vapor-deposition particles can be used for the opening regions 101a and the opening regions 101c. The same shall apply to the orifices 363b. This configuration simplifies the design of members such as the mask 100.

As described above, the apparatus 350 and the method for producing an organic EL element according to the present embodiment employs the vapor-deposition source 360 including the first orifices 363a corresponding to the first and third opening regions 101a and 101c, and second orifices 363b corresponding to the second and fourth opening regions 101b and 101d. Such correspondence enables decrease in the arrangement density of the nozzles 362, reducing scattering of vapor-deposition particles. The present embodiment therefore can decrease the probability that defects such as blurring occur compared with Embodiment 1.

The first orifices 363a are preferably arranged between the center portions of the first opening regions 101a and the center portions of the third opening regions 101c as viewed from the Z-axial direction, and the second orifices 363b are preferably arranged between the center portions of the second opening regions 101b and the center portions of the fourth opening regions 101d as viewed from the Z-axial direction. Thus, vapor-deposition particle regions with substantially the same density of particles in the vapor-deposition streams can be used for the opening regions 101a and the opening regions 101c. Also, vapor-deposition particle regions with substantially the same density of particles in the vapor-deposition streams can be used for the opening regions 101b and the opening region 101d. This configuration simplifies the design of members such as the mask 100.

### Embodiment 4

The features unique to the present embodiment are mainly described in the present embodiment, and the same points as in Embodiments 1 to 3 are not described. Also, the members having the same or similar functions in the present embodiment and Embodiments 1 to 3 are provided with the same or similar reference numerals, and are not described in the present embodiment.

The mask for production of an organic EL element according to the present embodiment is substantially the same as that of Embodiment 1 except that the mask further includes fifth and sixth opening regions as the opening regions arranged in a staggered pattern in addition to the first to fourth opening regions.

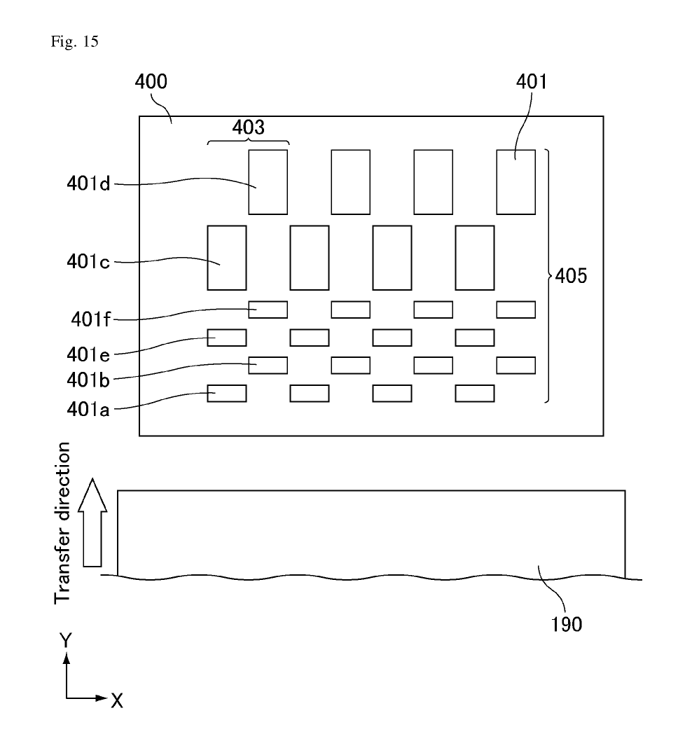

FIG. 15 is a schematic plan view of a mask for production of an organic EL element according to Embodiment 4.

As illustrated in FIG. 15, a mask 400 (patterning portion 405) for production of an organic EL element according to the present embodiment includes opening regions 401 in each of which mask openings (through holes, not illustrated in FIG. 15) for patterning are formed. The opening regions 401 are arranged in a staggered pattern with six rows and eight columns. This arrangement can give a higher degree of freedom to the design of the apparatus for producing an organic EL element including the mask 400, easing the restriction in the production apparatus.

It is important that the number of rows in the vertical direction (Y-axial direction) for the opening regions 401 is not smaller than six. Meanwhile, the number of columns in the horizontal direction (X-axial direction) for the opening regions 401 may be any number not smaller than two, and can appropriately be increased or decreased in accordance with the length in the X-axial direction of the vapor-deposition target region of the substrate.

The mask 400 (patterning portion 405) includes fifth opening regions 401e and sixth opening regions 401f as well as the first to fourth opening regions 401a to 401d as the opening regions 401 arranged in a staggered pattern.

The first to sixth opening regions 401a to 401f are arranged in a staggered pattern, and the first, second, fifth, sixth, third, and fourth opening regions 401a, 401b, 401e, 401f, 401c, and 401d are arranged alternately in the given order in the Y-axial direction. The opening regions 401a, 401e, and 401c are arranged at the same position in the X-axial direction. The opening regions 401b, 401f, and 401d are arranged at the same position in the X-axial direction. The opening regions 401a, 401b, 401e, 401f, 401c, and 401d are at different positions from each other in the Y-axial direction. The opening regions 401a, 401b, 401e, 401f, 401c, and 401d do not overlap each other in the Y-axial direction.

The mask 400 (patterning portion 405) is provided with opening blocks 403 including the first to sixth opening regions 401a to 401f. The opening blocks 403 are arranged at an equal pitch in the X-axial direction, and have the same configuration, i.e., the same opening pattern.

The apparatus for producing an organic EL element according to the present embodiment includes the mask 400 in place of the mask for production of an organic EL element according to Embodiment 1, and is configured to perform vapor deposition of a luminescent material on the substrate 190 while transferring (moving) the substrate 190 relatively to the mask 400 in the Y-axial direction at a constant speed such that the substrate 190 faces the opening regions 401a, 401b, 401e, 401f, 401c, and 401d in the given order. Similarly, the method for producing an organic EL element according to the present embodiment utilizes the mask 400 in place of the mask for production of an organic EL element according to Embodiment 1, and performs vapor deposition of a luminescent material on the substrate 190 while transferring (moving) the substrate 190 relatively to the mask 400 in the Y-axial direction at a constant speed such that the substrate 190 faces the opening regions 401a, 401b, 401e, 401f, 401c, and 401d in the given order. This means that vapor-deposition particles are vapor-deposited on the substrate 190 via the mask openings in the first opening regions 401a first; vapor-deposition particles are vapor-deposited on the substrate 190 via the mask openings in the second opening regions 401b; vapor-deposition particles are vapor-deposited on the substrate 190 via the mask openings in the fifth opening regions 401e; vapor-deposition particles are vapor-deposited on the substrate 190 via the mask openings in the sixth opening regions 401f; vapor-deposition particles are vapor-deposited on the substrate 190 via the mask openings in the third opening regions 401c; and then vapor-deposition particles are vapor-deposited on the substrate 190 via the mask openings in the fourth opening regions 401d.

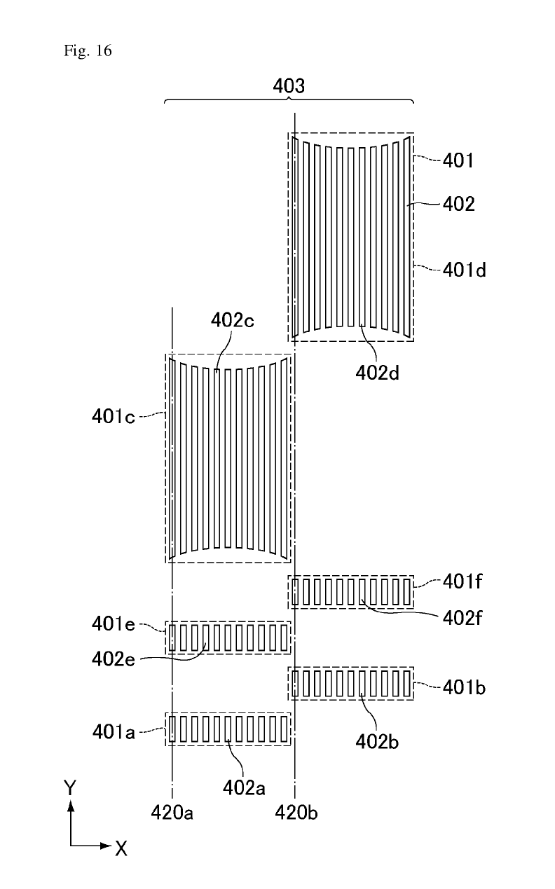

FIG. 16 is a schematic plan view of the mask for production of an organic EL element according to Embodiment 4, illustrating one opening block in an enlarged view.

As illustrated in FIG. 16, each opening region 401e and 401f is provided with mask openings (through holes) 402 as in the other opening regions 401. The fifth and sixth opening regions 401e and 401f are respectively provided with fifth and sixth mask openings 402e and 402f arranged in the X-axial direction. The mask openings 402e and 402f each have an elongated shape in a plan view (as viewed from the Z-axial direction), and are arranged in the Y-axial direction.

As in Embodiment 1, the opening regions 401a, 401b, 401c, and 401d respectively include the first, second, third, and fourth mask openings 402a, 402b, 402c, and 402d.

The fifth mask openings 402e are in one-to-one correspondence with the first mask openings 402a and with the third mask openings 402c. Each mask opening 402e is arranged at the same position as the corresponding mask openings 402a and 402c in the X-axial direction, and each mask opening 402e and the corresponding mask openings 402a and 402c are arranged on the same straight line 420a that is parallel to the Y-axial direction. Thereby, when the substrate (not illustrated in FIG. 16) is moved relatively to the mask 400 in the Y-axial direction, on the regions (sub-pixels) on which the vapor-deposition material has been vapor-deposited via the mask openings 402a, the vapor-deposition material is vapor-deposited again via the mask openings 402e, and then vapor-deposited again via the mask openings 402c.

Similarly, the sixth mask openings 402f are in one-to-one correspondence with the second mask openings 402b and with the fourth mask openings 402d. Each mask opening 402f is arranged at the same position as the corresponding mask openings 402b and 402d in the X-axial direction, and each mask opening 402d and the corresponding mask openings 402b and 402d are arranged on the same straight line 420b that is parallel to the Y-axial direction. Thereby, when the substrate is moved relatively to the mask 400 in the Y-axial direction, on the regions (sub-pixels) on which the vapor-deposition material has been vapor-deposited via the mask openings 402b, the vapor-deposition material is vapor-deposited again via the mask openings 402f, and then vapor-deposited again via the mask openings 402d.

Also, mask opening groups formed by all the fifth mask openings 402e and all the sixth mask openings 402f are arranged at an equal pitch in the X-axial direction as in the case of the mask opening groups formed by all the first mask openings 402a and all the second mask openings 402b. The pitch is made the same as the pixel pitch in the X-axial direction. This configuration allows formation of the stripe-patterned light-emitting layers on the entire vapor-deposition target region of the substrate just by one-time moving the substrate relatively to the mask 400 in the Y-axial direction.

The major feature of the present embodiment is that the length in the Y-axial direction of each of the fifth and sixth mask openings 402e and 402f as well as the first and second mask openings 402a and 402b is the shortest of all the lengths of the mask openings 402, and is shorter than the length in the Y-axial direction of each of the third and fourth mask openings 402c and 402d. As a result, in the region on which vapor deposition is performed via the first, fifth, and third mask openings 402a, 402e, and 402c (front-line region), an ultrathin contaminant layer, an ultrathin light-emitting layer, an ultrathin contaminant layer, an ultrathin light-emitting layer, a contaminant layer, and a common light-emitting layer having the desired thickness can be stacked in the given order on the hole injection/transport layer. In the region on which vapor deposition is performed via the second, sixth, and fourth mask openings 402b, 402f, and 402d (back-line region), an ultrathin contaminant layer, an ultrathin light-emitting layer, an ultrathin contaminant layer, an ultrathin light-emitting layer, a contaminant layer having a moderate thickness, and a common light-emitting layer having the desired thickness can be stacked in the given order on the hole injection/transport layer. This configuration can give a structure in which ultrathin contaminant layers and ultrathin light-emitting layers are alternately stacked (i.e., fragmented structure) in each of the front-line region and the back-line region. This configuration can therefore reduce the difference in hole injection efficiency and hole hopping transportability in the vicinity of the portion directly above the hole injection/transport layer between the front-line region and the back-line region compared with Embodiment 1. Thus, this configuration can reduce stitching unevenness compared with Embodiment 1.

As in the case of Embodiment 1, the thickness of each of the ultrathin light-emitting layers formed via the fifth and sixth mask openings 402e and 402f may be any thickness that allows hole hopping transport. The thickness is preferably not higher than 10%, more preferably not higher than 5%, of the thickness of the common light-emitting layer. The thickness is preferably not smaller than 1 nm (10 Å).

Each of the fifth and sixth mask openings 402e and 402f may have any length in the Y-axial direction that allows hole hopping transport through the ultrathin light-emitting layers formed via those openings. Still, the lengths are preferably set such that each ultrathin light-emitting layer has the favorable thickness described above. The length of each mask opening 402e is preferably not higher than 10%, more preferably not higher than 5%, of the length of the third mask opening 402c corresponding to the mask opening 402e. Also, the length of each mask opening 402e is preferably set such that the thickness of the ultrathin light-emitting layer formed via the mask opening 402e is not smaller than 1 nm. Similarly, the length of each mask opening 402f is preferably not higher than 10%, more preferably not higher than 5%, of the length of the fourth mask opening 402d corresponding to the mask opening 402f. Also, the length of each mask opening 402f is preferably set such that the thickness of the ultrathin light-emitting layer formed via the mask opening 402f is not smaller than 1 nm. The appropriate lower limit for each of the mask openings 402e and 402f can be easily calculated from the thickness of the ultrathin light-emitting layers, the moving rate of the substrate relative to the mask, and the film formation rate on the substrate surface.

The shape of each of the fifth and sixth mask openings 402e and 402f as viewed from the Z-axial direction may be any shape. The mask openings 102a and 102b may each be a slit opening elongated in the Y-axial direction as illustrated in FIG. 16. Each of the mask openings 402e and 402f may be divided into portions (mask opening portions), and the mask opening portions may be arranged in the Y-axial direction. In other words, each of the mask openings 402e and 402f may be a mask opening line including mask opening portions arranged in the Y-axial direction. In this case, the length in the Y-axial direction of each of the fifth and sixth mask openings 402e and 402f means the total length in the Y-axial direction of all the mask opening portions included in the mask openings 402e or 402f.

The length (width) in the X-axial direction of each of the fifth and sixth mask openings 402e and 402f may be any length, and can appropriately be set in accordance with the length (width) in the X-axial direction of the ultrathin light-emitting layer formed via the openings. The width of each of the mask openings 402e and 402f is preferably substantially the same as the width of the corresponding mask opening 402c or 402d. A difference in width between each of the mask openings 402e and 402f and the corresponding mask opening 402c or 402d may cause a difference in shape between the ultrathin light-emitting layers and the common light-emitting layer, leading to poor light emission.

The same number of the sixth mask openings 402f is formed in substantially the same pattern as in the case of the fifth mask openings 402e, but a different number of the sixth mask openings 402f may be formed in a different pattern. Meanwhile, the number of the sixth mask openings 402f is the same as that of the fourth mask openings 402d, and the number of the fifth mask openings 402e is the same as that of the third mask openings 402c.

The number of the mask openings 402e or 402f included in one of the opening regions 401e and 401f may be any number, and can appropriately be determined in accordance with the conditions such as the pitch of the nozzles of the vapor-deposition source, the range of vapor-deposition particles limited by the limiting plate, and the fineness of pixels.

Since the fifth and sixth mask openings 402e and 402f are provided to form ultrathin light-emitting layers, the lengths in the Y-axial direction of the mask openings 402e can be set independently of each other, and the lengths in the Y-axial direction of the mask openings 402f can be set independently of each other. Still, from the same viewpoint as in Embodiment 1, the lengths in the Y-axial direction of all the mask openings 402e and 402f are preferably substantially the same.

As described above, the mask 400 (patterning portion 405) for production of an organic EL element according to the present embodiment further includes the fifth and sixth opening regions 401e and 401f. The first to sixth opening regions 401a to 401f are arranged in a staggered pattern. The first, second, fifth, sixth, third, and fourth opening regions 401a, 401b, 401e, 401f, 401c, and 401d are arranged in the given order in the Y-axial direction (first direction). The fifth opening region 401e and the sixth opening region 401f respectively include the fifth mask openings 402e and the sixth mask openings 402f in the X-axial direction (second direction). The fifth mask openings 402e are arranged correspondingly to the first mask openings 402a and the third mask openings 402c. Each of the first mask openings 402a and the fifth mask opening 402e and third mask opening 402c corresponding to the first mask opening 402a are on the same straight line 420a that is parallel to the Y-axial direction. The sixth mask openings 402f are arranged correspondingly to the second mask openings 402b and the fourth mask openings 402d. Each of the second mask openings 402b and the sixth mask opening 402f and fourth mask opening 402d corresponding to the second mask opening 402b are on the same straight line 420b that is parallel to the Y-axial direction. The fifth mask openings 402e and the sixth mask openings 402f each have a shorter length in the Y-axial direction than each of the third mask openings 402c and the fourth mask openings 402d.

As described above, the mask 400 (patterning portion 405) for production of an organic EL element according to the present embodiment further includes the fifth and sixth opening regions 401e and 401f. The first to sixth opening regions 401a to 401f are arranged in a staggered pattern. The first, second, fifth, sixth, third, and fourth opening regions 401a, 401b, 401e, 401f, 401c, and 401d are arranged in the given order in the Y-axial direction. The fifth opening region 401e and the sixth opening region 401f respectively include the fifth mask openings 402e and the sixth mask openings 402f in the X-axial direction. Hence, this configuration can give eased restrictions in the apparatus for producing an organic EL element including the mask 400, and can pattern the entire vapor-deposition target region on the substrate 190 by one-time transfer of the substrate 190.

Also, the fifth mask openings 402e are arranged correspondingly to the first mask openings 402a and the third mask openings 402c. Each of the first mask openings 402a and the fifth mask opening 402e and third mask opening 402c corresponding to the first mask opening 402a are on the same straight line 420a that is parallel to the Y-axial direction. The sixth mask openings 402f are arranged correspondingly to the second mask openings 402b and the fourth mask openings 402d. Each of the second mask openings 402b and the sixth mask opening 402f and fourth mask opening 402d corresponding to the second mask opening 402b are on the same straight line 420b that is parallel to the Y-axial direction. Hence, when the substrate 190 is moved relatively to the vapor-deposition unit including the mask 400 in the Y-axial direction such that the first, second, fifth, sixth, third, and fourth opening regions 401a, 401b, 401e, 401f, 401c, and 401d face the substrate 190 in the given order, vapor-deposition particles can be vapor-deposited via the first mask openings 402a on the region corresponding to the first mask openings 402a, vapor-deposited via the second mask openings 402b on a region different from the region on which vapor deposition has been performed via the first mask openings 402a, vapor-deposited via the fifth mask openings 402e on the same region as the region on which vapor deposition has been performed via the first mask openings 402a, vapor-deposited via the sixth mask openings 402f on the same region as the region on which vapor deposition has been performed via the second mask openings 402b, vapor-deposited via the third mask openings 402c on the same region as the region on which vapor deposition has been performed via the first and fifth mask openings 402a and 402e, and then vapor-deposited via the fourth mask openings 402d on the same region as the region on which vapor deposition has been performed via the second and sixth mask openings 402b and 402f.

While vapor deposition via the mask openings 402 is not performed, the substrate 190 is exposed to contaminants. This produces a contaminant layer on the entire exposed surface of the substrate 190.

Also, the lengths in the Y-axial direction of the fifth mask openings 402e and the sixth mask openings 402f each are shorter than the length in the first direction of each of the third mask openings 402c and the fourth mask openings 402d. Hence, vapor-deposition time via the fifth and sixth mask openings 402e and 402f can be shortened. As a result, in the region on which vapor deposition is performed via the first, fifth, and third mask openings 402a, 402e, and 402c (front-line region), a very thin contaminant layer, a very thin light-emitting layer, a very thin contaminant layer, a very thin light-emitting layer, a contaminant layer, and a common light-emitting layer having the desired thickness can be formed in the given order on the hole injection/transport layer. In the region on which vapor deposition is performed via the second, sixth, and fourth mask openings 402b, 402f, and 402d (back-line region), a structure can be formed in which a very thin contaminant layer, a very thin light-emitting layer, a very thin contaminant layer, a very thin light-emitting layer, a contaminant layer having a moderate thickness, and a common light-emitting layer having the desired thickness are stacked in the given order on the hole injection/transport layer. This configuration can therefore reduce the difference in hole injection efficiency and hole hopping transportability in the vicinity of the portion directly above the hole injection/transport layer between the front-line region and the back-line region compared with Embodiment 1. Thus, this configuration can reduce luminance unevenness, particularly stitching unevenness, compared with Embodiment 1.

The lengths in the Y-axial direction of the fifth mask openings 402e and those of the sixth mask openings 402f are substantially the same. Therefore, when the mask 400 is bonded (for example, by spot welding) under tension to the mask frame, a reinforcing member, the tension applied to the mask 400 is uniform, whereby the position accuracy and pitch accuracy of the mask openings 402 can be further increased.

The expression “the lengths in the Y-axial direction of the fifth mask openings 402e and the lengths in the Y-axial direction of the sixth mask openings 402f are substantially the same” means that, when the maximum length and the minimum length of the lengths in the Y-axial direction of the fifth mask openings 402e and the sixth mask openings 402f are respectively defined as Ymax and Ymin, a value calculated from the above formula (1) is not higher than 10% (preferably not higher than 5%, more preferably not higher than 2%).

As in Embodiment 1, the vapor-deposition source in the present embodiment may include the first, second, fifth, sixth, third, and fourth orifices respectively corresponding to the first, second, fifth, sixth, third, and fourth opening regions 401a, 401b, 401e, 401f, 401c, and 401d. The vapor-deposition source may alternatively include first orifices corresponding to the first, fifth, and third opening regions 401a, 401e, and 401c or second orifices corresponding to the second, sixth, and fourth opening regions 401b, 401f, and 401d.

In the present embodiment, the four opening regions 401, namely the first, second, fifth, and sixth opening regions 401a, 401b, 401e, and 401f, are provided to form ultrathin light-emitting layers. Here, the number of opening regions 401 for forming ultrathin light-emitting layers is not particularly limited, and may be greater than four. For example, first, second, fifth, sixth, seventh, and eighth opening regions may be provided to form ultrathin light-emitting layers, and the first, second, fifth, sixth, seventh, eighth, third, and fourth opening regions may be arranged in the given order in the Y-axis direction.

### Embodiment 5

The features unique to the present embodiment are mainly described in the present embodiment, and the same points as in Embodiments 1 to 4 are not described. Also, the members having the same or similar functions in the present embodiment and Embodiments 1 to 4 are provided with the same or similar reference numerals, and are not described in the present embodiment.

In Embodiment 1, while vapor deposition via the fourth mask openings is performed, the region (front-line region) on which vapor deposition is performed via the first and third mask openings is exposed to contaminants. The contaminant layer formed on the common light-emitting layer having the desired thickness in the front-line region has a greater thickness than the region (back-line region) on which vapor deposition is performed via the second and fourth mask openings. The studies made by the inventors qualitatively show that a contaminant layer between the hole transport layer and the light-emitting layer more influences the luminance than a contaminant layer between the electron transport layer and the light-emitting layer. Still, both contaminant layers are barriers for carriers, and thus probably have variable influence on the luminance depending on the energy levels of the contaminant layers and the energy levels of the adjacent layers (e.g., hole injection layer, hole transport layer, electron-blocking layer, electron injection layer, electron transport layer, hole-blocking layer). That is, the contaminant layers are considered to have variable influence on the luminance depending on the structure and material of the organic EL elements. This consideration suggests that in Embodiment 1, the thick contaminant layer formed on the common light-emitting layer may possibly decrease the injection efficiency of electrons from the electron injection layer, electron transport layer, or hole-blocking layer, reducing the luminance. The stitching unevenness may therefore be further reduced in Embodiment 1. For this reason, the mask for production of an organic EL element according to the present embodiment further includes the fifth and sixth opening regions so as to form ultrathin light-emitting layers and ultrathin contaminant layers on the cathode side as well. Hereinafter, the electron injection layer, the electron transport layer, or the hole-blocking layer is also collectively referred to as an electron injection/transport layer.

The mask for production of an organic EL element according to the present embodiment is the same as that of Embodiment 4 except that the arrangement positions of the fifth and sixth opening regions are different.

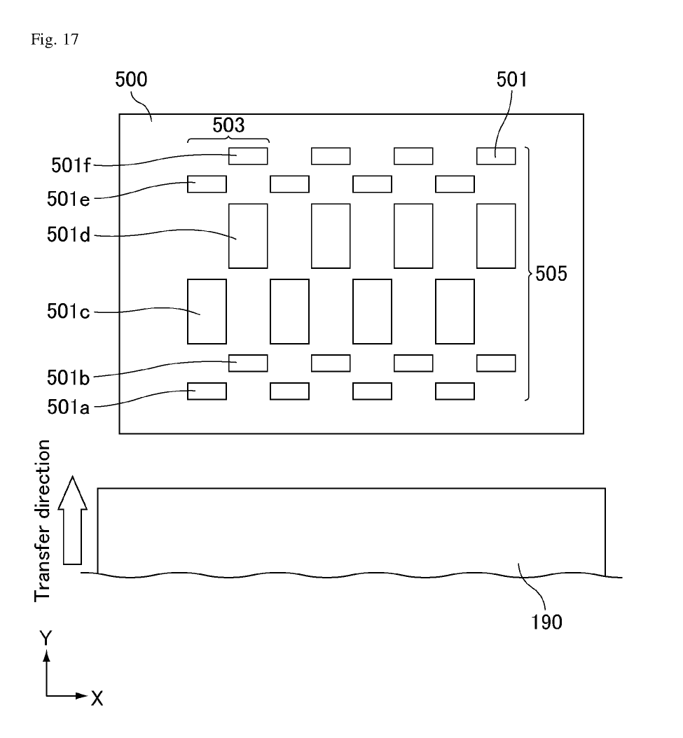

FIG. 17 is a schematic plan view of a mask for production of an organic EL element according to Embodiment 5.

As illustrated in FIG. 17, a mask 500 (patterning portion 505) for production of an organic EL element according to the present embodiment includes opening regions 501 in each of which mask openings (through holes, not illustrated in FIG. 17) for patterning are formed. The opening regions 501 are arranged in a staggered pattern with six rows and eight columns. This arrangement can give a higher degree of freedom to the design of the apparatus for producing an organic EL element including the mask 500, easing the restriction in the production apparatus.

It is important that the number of rows in the vertical direction (Y-axial direction) for the opening regions 501 is not smaller than six. Meanwhile, the number of columns in the horizontal direction (X-axial direction) for the opening regions 501 may be any number not smaller than two, and can appropriately be increased or decreased in accordance with the length in the X-axial direction of the vapor-deposition target region of the substrate.

The mask 500 (patterning portion 505) includes fifth opening regions 501e and sixth opening regions 501f as well as the first to fourth opening regions 501a to 501d as the opening regions 501 arranged in a staggered pattern.

The first to sixth opening regions 501a to 501f are arranged in a staggered pattern, and the first, second, third, fourth, fifth, and sixth opening regions 501a, 501b, 501c, 501d, 501e, and 501f are arranged alternately in the given order in the Y-axial direction. The opening regions 501a, 501c, and 501e are arranged at the same position in the X-axial direction. The opening regions 501b, 501d, and 501f are arranged at the same position in the X-axial direction. The opening regions 501a, 501b, 501c, 501d, 501e, and 501f are at different positions from each other in the Y-axial direction. The opening regions 501a, 501b, 501c, 501d, 501e, and 501f do not overlap each other in the Y-axial direction.

The mask 500 (patterning portion 505) is provided with opening blocks 503 including the first to sixth opening regions 501a to 501f. The opening blocks 503 are arranged at an equal pitch in the X-axial direction, and have the same configuration, i.e., the same opening pattern.

The apparatus for producing an organic EL element according to the present embodiment includes the mask 500 in place of the mask for production of an organic EL element according to Embodiment 1, and is configured to perform vapor deposition of a luminescent material on the substrate 190 while transferring (moving) the substrate 190 relatively to the mask 500 in the Y-axial direction at a constant speed such that the substrate 190 faces the opening regions 501a, 501b, 501c, 501d, 501e, and 501f in the given order. Similarly, the method for producing an organic EL element according to the present embodiment utilizes the mask 500 in place of the mask for production of an organic EL element according to Embodiment 1, and performs vapor deposition of a luminescent material on the substrate 190 while transferring (moving) the substrate 190 relatively to the mask 500 in the Y-axial direction at a constant speed such that the substrate 190 faces the opening regions 501a, 501b, 501c, 501d, 501e, and 501f in the given order. This means that vapor-deposition particles are vapor-deposited on the substrate 190 via the mask openings in the first opening regions 501a first; vapor-deposition particles are vapor-deposited on the substrate 190 via the mask openings in the second opening regions 501b; vapor-deposition particles are vapor-deposited on the substrate 190 via the mask openings in the third opening regions 501c; vapor-deposition particles are vapor-deposited on the substrate 190 via the mask openings in the fourth opening regions 501d; vapor-deposition particles are vapor-deposited on the substrate 190 via the mask openings in the fifth opening regions 501e; and then vapor-deposition particles are vapor-deposited on the substrate 190 via the mask openings in the sixth opening regions 501f.

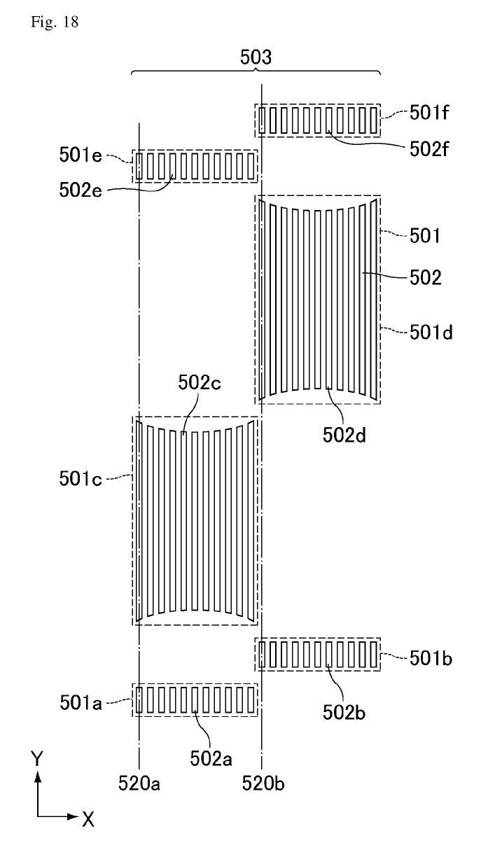

FIG. 18 is a schematic plan view of the mask for production of an organic EL element according to Embodiment 5, illustrating one opening block in an enlarged view.

As illustrated in FIG. 18, each opening region 501e and 501f is provided with mask openings (through holes) 502 as in the other opening regions 501. As in Embodiment 4, the opening regions 501a, 501b, 501c, 501d, 501e, and 501f respectively include first, second, third, fourth, fifth, and sixth mask openings 502a, 502b, 502c, 502d, 502e, and 502f. Thereby, when the substrate (not illustrated in FIG. 16) is moved relatively to the mask 500 in the Y-axial direction, on the regions (sub-pixels) on which the vapor-deposition material has been vapor-deposited via the mask openings 502a, the vapor-deposition material is vapor-deposited again via the mask openings 502c, and then vapor-deposited again via the mask openings 502e. Also, when the substrate is moved relatively to the mask 500 in the Y-axial direction, on the regions (sub-pixels) on which the vapor-deposition material has been vapor-deposited via the mask openings 502b, the vapor-deposition material is vapor-deposited again via the mask openings 502d, and then vapor-deposited again via the mask openings 502f.

Also in the present embodiment, as in Embodiment 4, the length in the Y-axial direction of each of the fifth and sixth mask openings 502e and 502f as well as the first and second mask openings 502a and 502b is the shortest of all the lengths of the mask openings 502, and is shorter than the length in the Y-axial direction of each of the third and fourth mask openings 502c and 502d. As a result, in the region on which vapor deposition is performed via the first, third, and fifth mask openings 502a, 502c, and 502e (front-line region), an ultrathin contaminant layer, an ultrathin light-emitting layer, a contaminant layer, a common light-emitting layer having the desired thickness, a contaminant layer having a moderate thickness, an ultrathin light-emitting layer, an ultrathin contaminant layer, and an electron injection/transport layer can be formed in the given order on the hole injection/transport layer. In the region on which vapor deposition is performed via the second, fourth, and sixth mask openings 502b, 502d, and 502f (back-line region), an ultrathin thin contaminant layer, an ultrathin light-emitting layer, a contaminant layer having a moderate thickness, a common light-emitting layer having the desired thickness, an ultrathin contaminant layer, an ultrathin light-emitting layer, an ultrathin contaminant layer, and an electron injection/transport layer can be formed in the given order on the hole injection/transport layer. Hence, based on the same principle as that on the hole injection/transport layer side, this configuration can increase the injection efficiency of electrons and allow smoother electron hopping transport. This configuration can therefore reduce the difference in electron injection efficiency and electron hopping transportability in the vicinity of the portion directly below the electron injection/transport layer between the front-line region and the back-line region compared with Embodiment 1. Thus, this configuration can reduce stitching unevenness compared with Embodiment 1.

As in the case of Embodiment 1, the thickness of each of the ultrathin light-emitting layers formed via the fifth and sixth mask openings 502e and 502f may be any thickness that allows electron hopping transport. The thickness is preferably not higher than 10%, more preferably not higher than 5%, of the thickness of the common light-emitting layer. The thickness is preferably not smaller than 1 nm (10 Å).

Each of the fifth and sixth mask openings 502e and 502f may have any length in the Y-axial direction that allows electron hopping transport through the ultrathin light-emitting layers formed via those openings. Still, the lengths are preferably set such that each ultrathin light-emitting layer has the favorable thickness described above. The length of each mask opening 502e is preferably not higher than 10%, more preferably not higher than 5%, of the length of the third mask opening 502c corresponding to the mask opening 502e. Also, the length of each mask opening 502e is preferably set such that the thickness of the ultrathin light-emitting layer formed via the mask opening 502e is not smaller than 1 nm. Similarly, the length of each mask opening 502f is preferably not higher than 10%, more preferably not higher than 5%, of the length of the fourth mask opening 502d corresponding to the mask opening 502f. Also, the length of each mask opening 502f is preferably set such that the thickness of the ultrathin light-emitting layer formed via the mask opening 502f is not smaller than 1 nm. The appropriate lower limit for each of the mask openings 502e and 502f can be easily calculated from the thickness of the ultrathin light-emitting layers, the moving rate of the substrate relative to the mask, and the film formation rate on the substrate surface.

The shape of each of the fifth and sixth mask openings 502e and 502f as viewed from the Z-axial direction may be any shape. The mask openings 502e and 502f may each be a slit opening elongated in the Y-axial direction as illustrated in FIG. 18. Each of the mask openings 502e and 502f may be divided into portions (mask opening portions), and the mask opening portions may be arranged in the Y-axial direction. In other words, each of the mask openings 502e and 502f may be a mask opening line including mask opening portions arranged in the Y-axial direction. In this case, the length in the Y-axial direction of each of the fifth and sixth mask openings 502e and 502f means the total length in the Y-axial direction of all the mask opening portions included in the mask openings 502e or 502f.

The length (width) in the X-axial direction of each of the fifth and sixth mask openings 502e and 502f may be any length, and can appropriately be set in accordance with the length (width) in the X-axial direction of the ultrathin light-emitting layer formed via the openings. The width of each of the mask openings 502e and 502f is preferably substantially the same as the width of the corresponding mask opening 502c or 502d. A difference in width between each of the mask openings 502e and 502f and the corresponding mask opening 502c or 502d may cause a difference in shape between the ultrathin light-emitting layers and the common light-emitting layer, leading to poor light emission.

The same number of the sixth mask openings 502f is formed in substantially the same pattern as in the case of the fifth mask openings 502e, but a different number of the sixth mask openings 502f may be formed in a different pattern. Meanwhile, the number of the sixth mask openings 502f is the same as that of the fourth mask openings 502d, and the number of the fifth mask openings 502e is the same as that of the third mask openings 502c.

The number of the mask openings 502e or 502f included in one of the opening regions 501e and 501f may be any number, and can appropriately be determined in accordance with the conditions such as the pitch of the nozzles of the vapor-deposition source, the range of vapor-deposition particles limited by the limiting plate, and the fineness of pixels.

Since the fifth and sixth mask openings 502e and 502f are provided to form ultrathin light-emitting layers, the lengths in the Y-axial direction of the mask openings 502e can be set independently of each other, and the lengths in the Y-axial direction of the mask openings 502f can be set independently of each other. Still, as in Embodiment 4, the lengths in the Y-axial direction of all the mask openings 502e and 502f are preferably substantially the same.

From the viewpoint of applying still more uniform tension to the mask 500 and further increasing the position accuracy and pitch accuracy of the mask openings 502, the lengths in the Y-axial direction of all the first, second, fifth, and sixth mask openings 502a, 502b, 502e, and 502f are preferably substantially the same. In the present embodiment, since the mask openings 502a and 502e are arranged symmetrically with the third mask openings 502c as the center and the mask openings 502b and 502f are symmetrically arranged with the fourth mask openings 502d as the center, setting the lengths in the Y-axial direction of the mask openings 502a, 502b, 502e, and 502f to the same length as described above enables application of very uniform tension to the mask 500.

As described above, the mask 500 (patterning portion 505) for production of an organic EL element according to the present embodiment further includes the fifth and sixth opening regions 501e and 501f. The first to sixth opening regions 501a to 501f are arranged in a staggered pattern. The first, second, third, fourth, fifth, and sixth opening regions 501a, 501b, 501c, 501d, 501e, and 501f are arranged in the given order in the Y-axial direction (first direction). The fifth opening region 501e and the sixth opening region 501f respectively include the fifth mask openings 502e and the sixth mask openings 502f in the X-axial direction (second direction). The fifth mask openings 502e are arranged correspondingly to the first mask openings 502a and the third mask openings 502c. Each of the first mask openings 502a and the fifth mask opening 502e and third mask opening 502c corresponding to the first mask opening 502a are on the same straight line 520a that is parallel to the Y-axial direction. The sixth mask openings 502f are arranged correspondingly to the second mask openings 502b and the fourth mask openings 502d. Each of the second mask openings 502b and the sixth mask opening 502f and fourth mask opening 502d corresponding to the second mask opening 502b are on the same straight line 520b that is parallel to the Y-axial direction. The fifth mask openings 502e and the sixth mask openings 502f each have a shorter length in the Y-axial direction than each of the third mask openings 502c and the fourth mask openings 502d.

As described above, the mask 500 (patterning portion 505) for production of an organic EL element according to the present embodiment further includes the fifth and sixth opening regions 501e and 501f. The first to sixth opening regions 501a to 501f are arranged in a staggered pattern. The first, second, third, fourth, fifth, and sixth opening regions 501a, 501b, 501c, 501d, 501e, and 501f are arranged in the given order in the Y-axial direction. The fifth opening region 501e and the sixth opening region 501f respectively include the fifth mask openings 502e and the sixth mask openings 502f in the X-axial direction. Hence, this configuration can give eased restrictions in the apparatus for producing an organic EL element including the mask 500, and can pattern the entire vapor-deposition target region on the substrate 190 by one-time transfer of the substrate 190.

Also, the fifth mask openings 502e are arranged correspondingly to the first mask openings 502a and the third mask openings 502c. Each of the first mask openings 502a and the fifth mask opening 502e and third mask opening 502c corresponding to the first mask opening 502a are on the same straight line 520a that is parallel to the Y-axial direction. The sixth mask openings 502f are arranged correspondingly to the second mask openings 502b and the fourth mask openings 502d. Each of the second mask openings 502b and the sixth mask opening 502f and fourth mask opening 502d corresponding to the second mask opening 502b are on the same straight line 520b that is parallel to the Y-axial direction. Hence, when the substrate 190 is moved relatively to the vapor-deposition unit including the mask 500 in the Y-axial direction such that the first, second, third, fourth, fifth, and sixth opening regions 501a, 501b, 501c, 501d, 501e, and 501f face the substrate 190 in the given order, vapor-deposition particles can be vapor-deposited via the first mask openings 502a on the region corresponding to the first mask openings 502a, vapor-deposited via the second mask openings 502b on a region different from the region on which vapor deposition has been performed via the first mask openings 502a, vapor-deposited via the third mask openings 502c on the same region as the region on which vapor deposition has been performed via the first mask openings 502a, vapor-deposited via the fourth mask openings 502d on the same region as the region on which vapor deposition has been performed via the second mask openings 502b, vapor-deposited via the fifth mask openings 502e on the same region as the region on which vapor deposition has been performed via the first and fifth mask openings 502a and 502e, and then vapor-deposited via the sixth mask openings 502f on the same region as the region on which vapor deposition has been performed via the second and sixth mask openings 502b and 502f.

While vapor deposition via the mask openings 502 is not performed, the substrate 190 is exposed to contaminants. This produces a contaminant layer on the entire exposed surface of the substrate 190.

Also, the fifth mask openings 502e and the sixth mask openings 502f each have a shorter length in the Y-axial direction than each of the third mask openings 502c and the fourth mask openings 502d. Hence, vapor-deposition time via the fifth and sixth mask openings 502e and 502f can be shortened. As a result, in the region on which vapor deposition is performed via the first, third, and fifth mask openings 502a, 502c, and 502e (front-line region), an ultrathin contaminant layer, an ultrathin light-emitting layer, a contaminant layer, a common light-emitting layer having the desired thickness, a contaminant layer having a moderate thickness, an ultrathin light-emitting layer, an ultrathin contaminant layer, and an electron injection/transport layer can be formed in the given order on the hole injection/transport layer. In the region on which vapor deposition is performed via the second, sixth, and fourth mask openings 502b, 502d, and 502f (back-line region), an ultrathin contaminant layer, an ultrathin light-emitting layer, a contaminant layer having a moderate thickness, a common light-emitting layer having the desired thickness, an ultrathin contaminant layer, an ultrathin light-emitting layer, an ultrathin contaminant layer, and an electron injection/transport layer can be formed in the given order on the hole injection/transport layer. This configuration can therefore reduce the difference in electron injection efficiency and electron hopping transportability in the vicinity of the portion directly below the electron injection/transport layer between the front-line region and the back-line region compared with Embodiment 1. Thus, this configuration can reduce luminance unevenness, particularly stitching unevenness, compared with Embodiment 1.

The lengths in the Y-axial direction of the fifth mask openings 502e and those of the sixth mask openings 502f are substantially the same. Therefore, when the mask 500 is bonded (for example, by spot welding) under tension to the mask frame, a reinforcing member, the tension applied to the mask 500 is uniform, whereby the position accuracy and pitch accuracy of the mask openings 502 can be further increased.

Preferably, the lengths in the Y-axial direction of the first mask openings 502a, the lengths in the Y-axial direction of the second mask openings 502b, the lengths in the Y-axial direction of the fifth mask openings 502e, and the lengths in the Y-axial direction of the sixth mask openings 502f are substantially the same. Thereby, the tension applied to the mask 500 can be further made uniform, and the position accuracy and pitch accuracy of the mask openings 502 can be further increased.

The expression “the lengths in the Y-axial direction of the fifth mask openings 502e and the lengths in the Y-axial direction of the sixth mask openings 502f are substantially the same” means that, when the maximum length and the minimum length of the lengths in the Y-axial direction of the fifth mask openings 502e and the sixth mask openings 502f are respectively defined as Ymax and Ymin, a value calculated from the above formula (1) is not higher than 10% (preferably not higher than 5%, more preferably not higher than 2%).

The expression “the lengths in the Y-axial direction of the first mask openings 502a, the lengths in the Y-axial direction of the second mask openings 502b, the lengths in the Y-axial direction of the fifth mask openings 502e, and the lengths in the Y-axial direction of the sixth mask openings 502f are substantially the same” means that, when the maximum length and the minimum length of the lengths in the Y-axial direction of the first mask openings 502a, the second mask openings 502b, the fifth mask openings 502e, and the sixth mask openings 502f are respectively defined as Ymax and Ymin, a value calculated from the above formula (1) is not higher than 10% (preferably not higher than 5%, more preferably not higher than 2%).

As in Embodiment 1, the vapor-deposition source in the present embodiment may include the first, second, third, fourth, fifth, and sixth orifices respectively corresponding to the first, second, third, fourth, fifth, and sixth opening regions 501a, 501b, 501c, 501d, 501e, and 501f. The vapor-deposition source may alternatively include first orifices corresponding to the first, third, and fifth opening regions 501a, 501c, and 501e or second orifices corresponding to the second, fourth, and sixth opening regions 501b, 501d, and 501f.

In the present embodiment, the four opening regions 501, namely the first, second, fifth, and sixth opening regions 501a, 501b, 501e, and 501f, are provided to form ultrathin light-emitting layers. Here, the number of opening regions 501 for forming ultrathin light-emitting layers is not particularly limited, and may be greater than four. For example, first, second, fifth, sixth, seventh, eighth, ninth, and tenth opening regions may be provided for formation of ultrathin light-emitting layers, and the first, second, seventh, eighth, third, fourth, ninth, tenth, fifth, and sixth opening regions may be arranged in the given order in the Y-axis direction.

### Embodiment 6

The features unique to the present embodiment are mainly described in the present embodiment, and the same points as in Embodiments 1 to 5 are not described. Also, the members having the same or similar functions in the present embodiment and Embodiments 1 to 5 are provided with the same or similar reference numerals, and are not described in the present embodiment.

The present embodiment is substantially the same as Embodiment 1 except that the transfer direction of the substrate is the opposite.

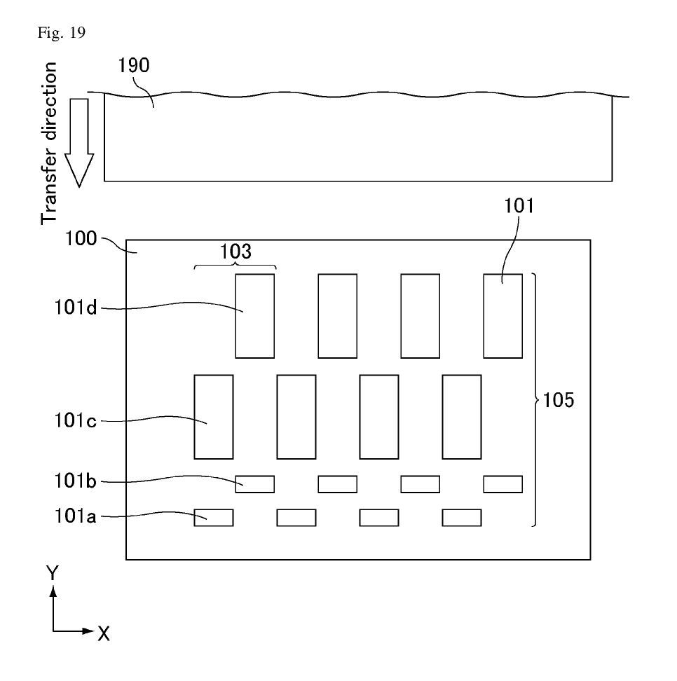

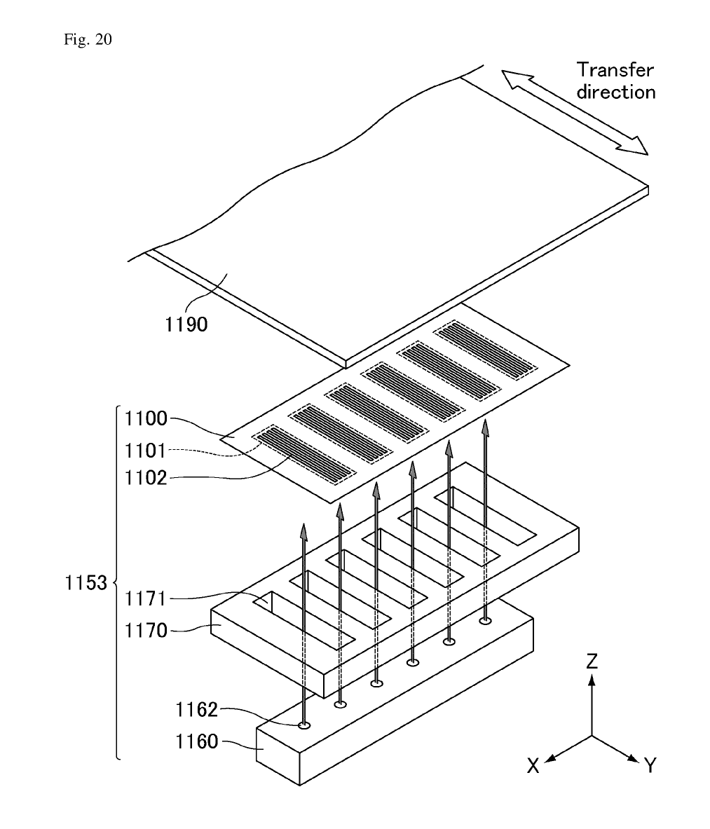

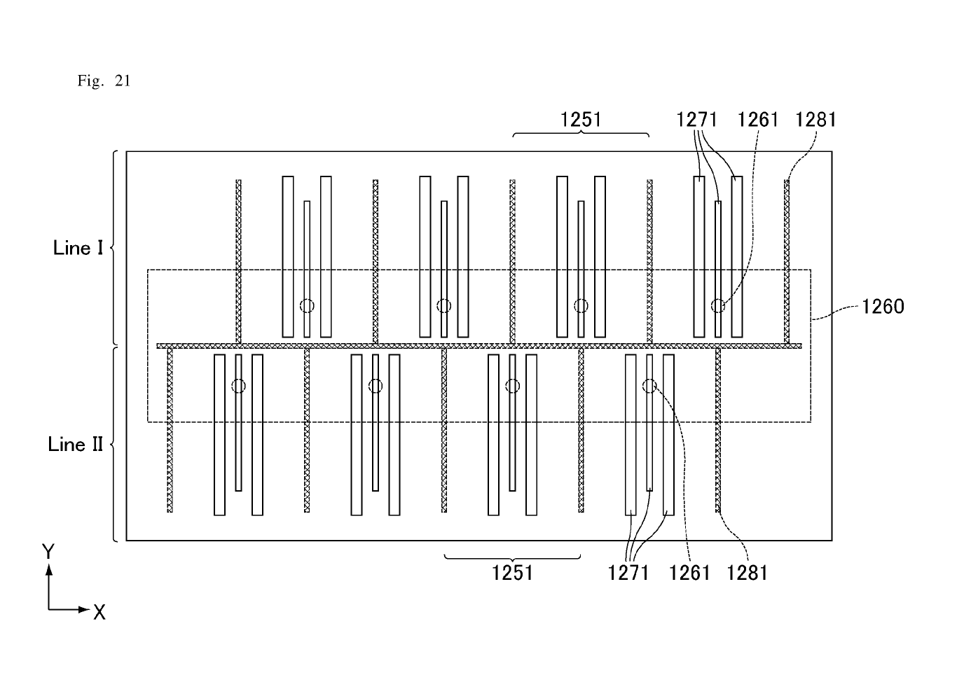

FIG. 19 is a schematic plan view of a mask for production of an organic EL element according to Embodiment 6.

As illustrated in FIG. 19, the present embodiment employs the mask 100 for production of an organic EL element according to Embodiment 1. The mask 100 in the present embodiment is disposed such that the fourth, third, second, and first opening regions 101d, 101c, 101b, and 101a face the substrate 190 in the given order, and the direction in which the substrate 190 is moved relatively to the mask 100 is opposite to that in Embodiment 1. That is, in the present embodiment, the substrate 190 is moved relatively to the mask 100 in the direction opposite to the Y-axial direction.

The apparatus and method for producing an organic EL element according to the present embodiment perform vapor deposition of a luminescent material on the substrate 190 while transferring (moving) the substrate 190 relatively to the mask 100 in the direction opposite to the Y-axial direction at a constant speed such that the substrate 190 faces the opening regions 101d, 101c, 101b, and 101a in the given order. This means that vapor-deposition particles are vapor-deposited on the substrate 190 via the mask openings in the fourth opening regions 101d first; vapor-deposition particles are vapor-deposited on the substrate 190 via the mask openings in the third opening regions 101c; vapor-deposition particles are vapor-deposited on the substrate 190 via the mask openings in the second opening regions 101b; and then vapor-deposition particles are vapor-deposited on the substrate 190 via the mask openings in the first opening regions 101a.

As a result, in the region on which vapor deposition is performed via the first and third mask openings 102a and 102c (front-line region), a contaminant layer having a moderate thickness, a common light-emitting layer having the desired thickness, a contaminant layer, an ultrathin light-emitting layer, an ultrathin contaminant layer, and an electron injection/transport layer can be formed in the given order on the hole injection/transport layer. In the region on which vapor deposition is performed via the second and fourth mask openings 102b and 102d (back-line region), an ultrathin contaminant layer, a common light-emitting layer having the desired thickness, a contaminant layer having a moderate thickness, an ultrathin light-emitting layer, an ultrathin contaminant layer, and an electron injection/transport layer can be formed in the given order on the hole injection/transport layer. This configuration therefore allows smoother electron hopping transport, leading to efficient injection of electrons into the common light-emitting layer having the desired thickness, on the electron injection/transport layer side. This configuration can therefore reduce the difference in electron injection efficiency and electron hopping transportability in the vicinity of the portion directly below the electron injection/transport layer between the front-line region and the back-line region. Thus, this configuration can reduce stitching unevenness.

As described above, the apparatus for producing an organic EL element according to the present embodiment is an apparatus for producing an organic EL element through formation of a film on the substrate 190, including the mask 100 for production of an organic EL element according to the present embodiment; the vapor-deposition unit 153 including the vapor-deposition source 160 configured to eject vapor-deposition particles; and the transfer mechanism 152 configured to move the substrate 190 relatively to the vapor-deposition unit 153 in the Y-axial direction (first direction), with the substrate 190 being away from the mask 100. The mask 100 is disposed such that the fourth, third, second, and first opening regions 101d, 101c, 101b, and 101a face the substrate 190 in the given order. Hence, this configuration can give eased restrictions in the apparatus for producing an organic EL element according to the present embodiment and can pattern the entire vapor-deposition target region on the substrate 190 by one-time transfer of the substrate 190 by the transfer mechanism, as in Embodiment 1.

Also, vapor-deposition particles can be vapor-deposited via the fourth mask openings 102d on the region corresponding to the fourth mask openings 102d, vapor-deposited via the third mask openings 102c on a region different from the region on which vapor deposition has been performed via the fourth mask openings 102d, vapor-deposited via the second mask openings 102b on the same region as the region on which vapor deposition has been performed via the fourth mask openings 102d, and then vapor-deposited via the first mask openings 102a on the same region as the region on which vapor deposition has been performed via the third mask openings 102c.

While vapor deposition via the mask openings 102 is not performed, the substrate 190 is exposed to contaminants. This produces a contaminant layer on the entire exposed surface of the substrate 190.

As described above, in the region on which vapor deposition is performed via the first and third mask openings 102a and 102c (front-line region), a contaminant layer having a moderate thickness, a common light-emitting layer having the desired thickness, a contaminant layer, an ultrathin light-emitting layer, an ultrathin contaminant layer, and an electron injection/transport layer can be formed in the given order on the hole injection/transport layer. In the region on which vapor deposition is performed via the second and fourth mask openings 102b and 102d (back-line region), an ultrathin contaminant layer, a common light-emitting layer having the desired thickness, a contaminant layer having a moderate thickness, an ultrathin light-emitting layer, an ultrathin contaminant layer, and an electron injection/transport layer can be formed in the given order on the hole injection/transport layer. This configuration therefore allows smoother electron hopping transport, leading to efficient injection of electrons into the common light-emitting layer having the desired thickness, in the back-line region. This configuration can prevent a decrease in the luminance in the back-line region, and can reduce the difference in luminance between the front-line region and the back-line region. That is, this configuration can prevent luminance unevenness, particularly stitching unevenness.

Also, the method for producing an organic EL element according to the present embodiment is a method for producing an organic EL element with use of the mask 100 for production of an organic EL element according to the present embodiment. The method for producing an organic EL element according to the present embodiment includes a light-emitting layer vapor-deposition step S4 of causing the vapor-deposition particles to adhere to the substrate 190 via the mask 100 while moving in the Y-axial direction the substrate 190 relatively to the vapor-deposition unit 153 including the mask 100 and the vapor-deposition source 160 configured to eject vapor-deposition particles, with the substrate 190 being away from the mask 100. The mask 100, in the light-emitting layer vapor-deposition step S4, is disposed such that the fourth, third, second, and first opening regions 101d, 101c, 101b, and 101a face the substrate 190 in the given order. Accordingly, similarly to the apparatus for producing an organic EL element according to the present embodiment, the method can give reduced luminance unevenness and eased restrictions in the apparatus for producing an organic EL element.

In the present embodiment, the two opening regions 101, namely the first and second opening regions 101a and 101b, are provided to form ultrathin light-emitting layers. Here, the number of opening regions 101 for forming ultrathin light-emitting layers is not particularly limited, and may be greater than two. For example, in place of the mask 100 for production of an organic EL element according to Embodiment 1, the mask 400 for production of an organic EL element according to Embodiment 4 which includes the first, second, fifth, and sixth opening regions may be used.

Hereinafter, modified examples of Embodiments 1 to 6 are described.

The masks of the embodiments and the apparatuses and methods for producing an organic EL element according to the embodiments may be applied to a vapor-deposition step other than the light-emitting layer vapor-deposition step S4, such as the electron transport layer vapor-deposition step S5. Thereby, carrier hopping transport can be promoted also at the interface with an organic EL layer other than the light-emitting layer. In this manner, a thin film in a vapor-deposition step other than the light-emitting layer vapor-deposition step may be patterned as in the light-emitting layer vapor-deposition step. For example, an electron transport layer may be separately formed for sub-pixels of each color.

The orientations of the constituent members of the apparatuses for producing an organic EL element according to the embodiments are not particularly limited. For example, all the constituent members described above may be disposed upside down, or the substrate may be placed vertically and vapor-deposition streams may be sprayed from a horizontal direction (side direction).

An organic EL display device provided with the organic EL elements produced by the apparatus and method for producing an organic EL element according to any of the embodiments may be a monochrome display device, and each pixel may not be divided into sub-pixels. In such a case, in the light-emitting layer vapor-deposition step, vapor deposition of a luminescent material of one color may be performed to form a light-emitting layer of one color.

The embodiments described above may appropriately be combined within the spirit of the present invention. Also, a modified example of each embodiment may be combined with any of the other embodiments. For example, additional limiting plates may be provided to the apparatus for producing an organic EL element according to Embodiment 4 or 5, and the additional limiting plates may separate the space between the mask for production of an organic EL element and the limiting plate into six spaces corresponding to the respective first, second, third, fourth, fifth, and sixth opening regions.

### Comparative Embodiment 2

The present comparative embodiment is substantially the same as Embodiment 1 except that the mask for production of an organic EL element according to Embodiment 1 is divided into a small mask including the first and second opening regions and a small mask including the third and fourth opening regions.

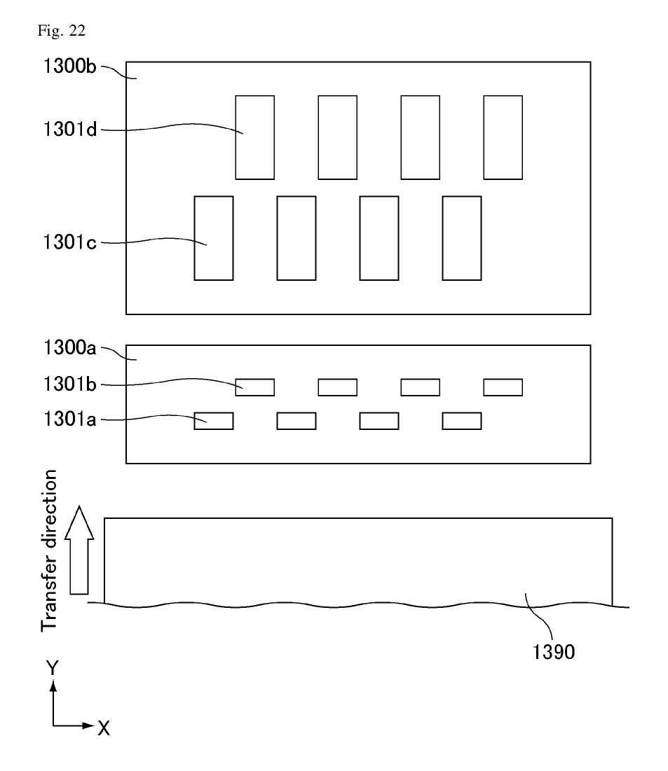

FIG. 22 is a schematic plan view of a mask for production of an organic EL element according to Comparative Embodiment 2 on which the inventors made studies.

As illustrated in FIG. 22, the present comparative embodiment utilizes a small mask 1300a including first and second opening regions 1301a and 1301b and a small mask 1300b including third and fourth opening regions 1301c and 1301d. The present comparative embodiment seems to be able to provide the same effects as Embodiment 1, but has the following problems.

The first opening regions 1301a and the third opening regions 1301c are provided for the same region, and the second opening regions 1301b and the fourth opening regions 1301d are provided for the same region. Between the opening regions 1301a and the opening regions 1301c and between the opening regions 1301b and the opening regions 1301d, the position (pitch) accuracies have to be matched exactly and also the opening accuracies have to be matched exactly. However, in the case of welding the masks 1300a and 1300b to one mask frame, it is difficult to match the position accuracies and the opening accuracies between the masks 1300a and 1300b. The masks 1300a and 1300b each are strip shaped, and the two sides of each of the masks 1300a and 1300b alone are bonded to the mask frame. Hence, this method is not likely to achieve a higher accuracy than a common method of bonding the four sides of a mask to the mask frame.

A method of using one mask frame for each of the masks 1300a and 1300b is possible, and this method can weld the four sides of each of the masks 1300a and 1300b to the mask frame. Still, this method must accurately bond the masks 1300a and 1300b to the respective mask frames and accurately dispose the mask and mask frame groups. In addition, the increased number of members leads to a failure in achieving high accuracy. With this method, the size of the mask frame has to be changed to conform to the size of each of the masks 1300a and 1300b. The outer shapes of the masks 1300a and 1300b may be made the same, but this option is not favorable in terms of contamination as described below.

Generally, in the case of arranging opening regions in a staggered pattern, a shorter space in the transfer direction of the substrate between adjacent opening regions is more preferred because the time for the substrate to be exposed to contaminants can be shortened.

However, in the present comparative embodiment, if the opening regions 1301a to 1301d are arranged in a staggered pattern with use of different masks 1300a and 1300b, exclusion regions of the masks 1300a and 1300b (e.g., regions in which mask openings cannot be formed due to contact with the welding machine) are generated, and thus the space between adjacent opening regions cannot be narrowed down. Also, as described above, in the case of making the outer shapes of the masks 1300a and 1300b the same, the mask openings formed in the first and second opening regions 1301a and 1301b are very short. Hence, the exclusion regions of the mask 1300a becomes very wide, leading to a long interval between the end of vapor deposition via the first and second opening regions 1301a and 1301b and the start of vapor deposition via the third and fourth opening regions 1301c and 1301d. As a result, the amount of contaminants adhering to a substrate 1390 increases.

In contrast, Embodiments 1 to 6 each employ arrangement in which opening regions in one mask are in a staggered pattern, and thus are free from such problems.

### REFERENCE SIGNS LIST

1: organic EL display device
2: pixel
2R, 2G, 2B: sub-pixel
10: TFT substrate
11: insulating substrate
12: TFT
13: interlayer film
13a: contact hole
14: conductive line
15: edge cover
15R, 15G, 15B: opening
20: organic EL element
21: first electrode
22: hole injection layer (organic layer)
23: hole transport layer (organic layer)
24R, 24G, 24B: light-emitting layer (organic layer)
25: electron transport layer (organic layer)
26: electron injection layer (organic layer)
27: second electrode
30: adhesive layer
40: sealing substrate
100, 400, 500: mask for production of an organic EL element
101, 401, 501: opening region
101a, 401a, 501a: first opening region
101b, 401b, 501b: second opening region
101c, 401c, 501c: third opening region
101d, 401d, 501d: fourth opening region
102, 402: mask opening
102a, 402a, 502a: first mask opening
102b, 402b, 502b: second mask opening
102c, 402c, 502c: third mask opening
102d, 402d, 502d: fourth mask opening
103, 403, 503: opening block
104: edge
105, 405, 505: patterning portion
120a, 120b, 420a, 420b, 520a, 520b: straight line
150, 250, 350: apparatus for producing an organic EL element
151: substrate holder
152: transfer mechanism
153, 253: vapor-deposition unit
160, 360: vapor-deposition source
161: scattering portion
162, 362: nozzle
163, 363: orifice
163a, 363a: first orifice
163b, 363b: second orifice
163c: third orifice
163d: fourth orifice
170: limiting plate
171: opening
171a: first opening
171b: second opening
171c: third opening
171d: fourth opening
190: substrate
191: vapor-deposition stream
192: patterned film (vapor-deposition film)
193a to 193d: space
280, 280a to 280g: additional limiting plate
401e, 501e: fifth opening region
401f, 501f: sixth opening region
402e, 502e: fifth mask opening
402f, 502f: sixth mask opening

1: A mask for production of an organic electroluminescent element, comprising
a patterning portion including mask openings for patterning,
the patterning portion including first to fourth opening regions arranged in a staggered pattern,
the first, second, third, and fourth opening regions being arranged in the given order in a first direction that is parallel to the patterning portion,
the first opening region, the second opening region, the third opening region, and the fourth opening region respectively including first mask openings, second mask openings, third mask openings, and fourth mask openings in a second direction that is parallel to the patterning portion and perpendicular to the first direction,
the third mask openings being arranged correspondingly to the first mask openings,
each of the first mask openings and the third mask opening corresponding to the first mask opening being on the same straight line that is parallel to the first direction,
the fourth mask openings being arranged correspondingly to the second mask openings,
each of the second mask openings and the fourth mask opening corresponding to the second mask opening being on the same straight line that is parallel to the first direction,
the mask including no mask openings on the side of the first opening region opposite to the third opening region,
the first mask openings and the second mask openings each having a shorter length in the first direction than each of the third mask openings and fourth mask openings.

2. The mask for production of an organic electroluminescent element according to claim 1,
wherein the first mask openings and the second mask openings have substantially the same length in the first direction.

3: The mask for production of an organic electroluminescent element according to claim 1,
wherein the patterning portion further includes fifth and sixth opening regions,
the first to sixth opening regions are arranged in a staggered pattern,
the first, second, fifth, sixth, third, and fourth opening regions are arranged in the given order in the first direction,
the fifth opening region and the sixth opening region respectively include fifth mask openings and sixth mask openings in the second direction,
the fifth mask openings are arranged correspondingly to the first mask openings and the third mask openings,
each of the first mask openings and the fifth mask opening and third mask opening corresponding to the first mask opening are on the same straight line that is parallel to the first direction,
the sixth mask openings are arranged correspondingly to the second mask openings and the fourth mask openings,
each of the second mask openings and the sixth mask opening and fourth mask opening corresponding to the second mask opening are on the same straight line that is parallel to the first direction, and
the fifth mask openings and the sixth mask openings each have a shorter length in the first direction than each of the third mask openings and fourth mask openings.

4: The mask for production of an organic electroluminescent element according to claim 1,
wherein the patterning portion further includes fifth and sixth opening regions,
the first to sixth opening regions are arranged in a staggered pattern,
the first, second, third, fourth, fifth, and sixth opening regions are arranged in the given order in the first direction,
the fifth opening region and the sixth opening region respectively include fifth mask openings and sixth mask openings in the second direction,
the fifth mask openings are arranged correspondingly to the first mask openings and the third mask openings,
each of the first mask openings and the fifth mask opening and third mask opening corresponding to the first mask opening are on the same straight line that is parallel to the first direction,
the sixth mask openings are arranged correspondingly to the second mask openings and the fourth mask openings,
each of the second mask openings and the sixth mask opening and fourth mask opening corresponding to the second mask opening are on the same straight line that is parallel to the first direction, and
the fifth mask openings and the sixth mask openings each have a shorter length in the first direction than each of the third mask openings and fourth mask openings.

5: The mask for production of an organic electroluminescent element according to claim 3,
wherein the fifth mask openings and the sixth mask openings have substantially the same length in the first direction.

6: An apparatus for producing an organic electroluminescent element through formation of a film on a substrate, comprising:
a vapor-deposition unit including the mask for production of an organic electroluminescent element according to claim 1 and a vapor-deposition source configured to eject vapor-deposition particles; and
a transfer mechanism configured to move the substrate relatively to the vapor-deposition unit in the first direction, with the substrate being away from the mask for production of an organic electroluminescent element,
the mask for production of an organic electroluminescent element being disposed such that the first, second, third, and fourth opening regions face the substrate in the given order or the fourth, third, second, and first opening regions face the substrate in the given order.

7: The apparatus for producing an organic electroluminescent element according to claim 6,
wherein the vapor-deposition source includes first, second, third, and fourth orifices respectively corresponding to the first, second, third, and fourth opening regions.

8: The apparatus for producing an organic electroluminescent element according to claim 6,
wherein the vapor-deposition source includes a first orifice corresponding to the first and third opening regions, and a second orifice corresponding to the second and fourth opening regions.

9: The apparatus for producing an organic electroluminescent element according to claim 8,
wherein the first orifice is positioned at the center between a center portion of the first opening region and a center portion of the third opening region as viewed from a third direction that is perpendicular to the first direction and the second direction, and
the second orifice is positioned at the center between a center portion of the second opening region and a center portion of the fourth opening region as viewed from the third direction.

10: The apparatus for producing an organic electroluminescent element according to claim 6, further comprising a limiting plate disposed between the mask for production of an organic electroluminescent element and the vapor-deposition source,
wherein the limiting plate includes first, second, third, and fourth openings respectively corresponding to the first, second, third, and fourth opening regions.

11: The apparatus for producing an organic electroluminescent element according to claim 10, further comprising additional limiting plates disposed between the mask for production of an organic electroluminescent element and the limiting plate,
wherein the additional limiting plates separate a space between the mask for production of an organic electroluminescent element and the limiting plate into four spaces respectively corresponding to the first, second, third, and fourth opening regions.

12: A method for producing an organic electroluminescent element with use of a mask for production of an organic electroluminescent element,
the mask for production of an organic electroluminescent element including a patterning portion including mask openings for patterning,
the patterning portion including first to fourth opening regions arranged in a staggered pattern,
the first, second, third, and fourth opening regions being arranged in the given order in a first direction that is parallel to the patterning portion,
the first opening region, the second opening region, the third opening region, and the fourth opening region respectively including first mask openings, second mask openings, third mask openings, and fourth mask openings in a second direction that is parallel to the patterning portion and perpendicular to the first direction,
the third mask openings being arranged correspondingly to the first mask openings,
each of the first mask openings and the third mask opening corresponding to the first mask opening being on the same straight line that is parallel to the first direction,
the fourth mask openings being arranged correspondingly to the second mask openings,
each of the second mask openings and the fourth mask opening corresponding to the second mask opening being on the same straight line that is parallel to the first direction,
the mask including no mask openings on the side of the first opening region opposite to the third opening region,
the first mask openings and the second mask openings each having a shorter length in the first direction than each of the third mask openings and fourth mask openings,
the production method comprising:
a vapor-deposition step of causing vapor-deposition particles to adhere to the substrate via the mask for production of an organic electroluminescent element while moving in the first direction the substrate relatively to a vapor-deposition unit including the mask for production of an organic electroluminescent element and a vapor-deposition source configured to eject vapor-deposition particles, with the substrate being away from the mask for production of an organic electroluminescent element,
the mask for production of an organic electroluminescent element, in the vapor-deposition step, being disposed such that the first, second, third, and fourth opening regions face the substrate in the given order or the fourth, third, second, and first opening regions face the substrate in the given order.
